(19) United States
(12) Patent Application Publication
(10) Pub. No.: US 2011/0058126 A1
(43) Pub. Date: Mar. 10, 2011

(54) SEMICONDUCTOR ELEMENT, METHOD OF MANUFACTURING FINE STRUCTURE ARRANGING SUBSTRATE, AND DISPLAY ELEMENT

(76) Inventors: Yasunobu Okada, Osaka-shi (JP); Akihide Shibata, Osaka-shi (JP); Yoshiharu Nakajima, Osaka-shi (JP); Hiroshi Iwata, Osaka-shi (JP); Ai Naitou, Osaka-shi (JP); Yutaka Takafuji, Osaka-shi (JP); Tetsu Negishi, Osaka-shi (JP)

(21) Appl. No.: 12/867,725

(22) PCT Filed: Feb. 10, 2009
(86) PCT No.: PCT/JP2009/052238

§ 371 Date: Nov. 23, 2010

(30) Foreign Application Priority Data
Feb. 14, 2008 (JP) 2008-033289
Feb. 14, 2008 (JP) 2008-033561

(51) Int. Cl. G02F 1/1333; H01L 29/41; H01L 21/44

(52) U.S. Cl. 349/84; 257/773; 438/666; 257/E21.477; 257/E29.112; 977/762

(57) ABSTRACT

With reference to a direction perpendicular to a direction of forming electrodes to which a voltage can be applied, fine structures are each arranged within ±5 degrees at a substantially even interval, and a semiconductor element is formed by using the fine structures. On an insulating substrate, at least two electrodes are arranged at a predetermined interval, and there are formed one or more fine structure arranging regions, each of which is formed by a unit of the two electrodes. A semiconductor element electrode is made in contact with the plurality of the fine structures, each having two ends in contact with the two electrodes and a length in a longitudinal direction of a nano order to a micron order, and arranged within ±5 degrees with reference to the direction perpendicular to the direction of forming the electrodes.

### TECHNICAL FIELD

The present invention relates to a semiconductor element formed by using fine structures arranged on a substrate, and a method of manufacturing the substrate onto which the fine structures are arranged. Furthermore, the present invention relates to a display element provided with the semiconductor element formed by using the fine structures arranged on the substrate. More specifically, the present invention relates to a semiconductor element using fine structures that are arranged regularly, and a method of manufacturing a fine structure arranging substrate utilizing a method of arranging the fine structures at desired positions and a method of removing the fine structures that are not arranged as desired. Furthermore, the present invention relates to the fine structure arranging substrate manufactured by the aforesaid method, and a semiconductor element and a display element utilizing the fine structures that are arranged between electrodes by the aforesaid method.

### BACKGROUND ART

In recent years, a study on an application of nanostructures such as nanowires or nanotubes as a semiconductor element is widely conducted. For example, Patent Document 1 discloses a quantum wire transistor formed by bundling a plurality of silicon nanowires and a method of manufacturing the same. Further, a method of assembling a large number of silicon quantum wires on a large-scale substrate is disclosed in Non-Patent Document 1, which makes use of a Langmuir-Blodget method and distributes the created silicon quantum wires onto the large-scale substrate after separating the wires.

Furthermore, Patent Document 2 discloses an invention that, while an AC voltage is applied between a source electrode and a drain electrode, dropped to an interelectrode area are droplets of a carbon nanotube solution in which carbon nanotubes are dispersed in a solvent, and then the solvent is removed. According to this, an orientation direction of the carbon nanotubes can be controlled. Further, Patent Document 2 discloses a technique that a DC voltage is applied between the electrodes to remove carbon nanotubes having conductive property and exclusively leave carbon nanotubes having semiconductor property.

Patent Document 1: Japanese Unexamined Patent Publication No. 2005-197612

Patent Document 2: Japanese Unexamined Patent Publication No. 2004-71654

Non-Patent Document 1: Nano Letters, Vol. 3, No. 7 (2003) p. 951-954

### DISCLOSURE OF THE INVENTION

### Problems to be Solved by the Invention

However, according to the methods described in the aforesaid documents, the nanostructures are not sufficiently controlled to be arranged as desired. In order to manufacture a semiconductor element or a display element using the nanostructures as devices, it is essential for the nanostructures to have desired arrangement. “Desired arrangement” herein refers to a regular arrangement of the nanostructures at even intervals along a desired direction. Specifically, it is essential for 2 to 200 pieces of the nanostructures to be arranged in an identical direction, at even intervals between the nanostructures within a range from 1 to 5 μm. On the other hand, also required is a technique to remove nanostructures having undesirable arrangement while maintaining nanostructures having the desired arrangement as they are. “Undesirable arrangement” refers to arrangement of the nanostructures not being at the desired positions but being arranged in random directions, and being arranged intersecting one another.

As a result of a study of the arrangement of the nanostructures by the present inventors, it has been found that the desired arrangement can be obtained when the fine structures such as silicon nanowires are arranged at substantially even intervals within ±5 degrees, with reference to a direction perpendicular to a parallel direction along which two electrodes are arranged.

Therefore, the present invention aims to provide a semiconductor element using the fine structures such as silicon nanowires arranged at substantially even intervals within ±5 degrees, with reference to the direction perpendicular to the parallel direction along which the two electrodes are aligned. Furthermore, the present invention aims to provide an integrated circuit and a display element including the semiconductor element.

Further, the present invention aims to realize a method of arranging the fine structures as desired and a method of preferentially removing the fine structures that are not arranged as desired. Moreover, the present invention aims to provide a fine structure arranging substrate in which the fine structures are arranged as desired and the fine structures having undesirable arrangement are removed according to the method of the present invention. Yet further, the present invention aims to provide a semiconductor element and a display element using the fine structures that are arranged as desired on the fine structure arranging substrate.

### Means for Solving the Problems

In order to solve the above problems, a semiconductor element of the present invention includes an insulating substrate on which at least two electrodes are arranged at a predetermined interval, and one or more fine structure arranging regions each formed by a unit of the two electrodes are formed; a plurality of fine structures, each of which has two ends in contact with the two electrodes, and a length of a nano order to a micron order, and arranged within ±5 degrees with reference to a direction perpendicular to a parallel direction along which the two electrodes are arranged; and a semiconductor element electrode in contact with the plurality of the fine structures.

According to the above, there can be realized a semiconductor element in which performance is improved, a yield is increased, and variations are suppressed.

Further, the present invention provides a method of manufacturing a fine structure arranging substrate which solves the above problem, and in a first embodiment, the method includes a fine structure dispersed solution producing step of dispersing fine structures having lengths of a nano order to a micron order in a solution; a substrate forming step of forming one or more fine structure arranging regions in which a first electrode and a second electrode are arranged on an insulating substrate at an interval shorter than the length of the fine structure; an application step of applying the fine structure dispersed solution on the insulating substrate; a fine structure arranging step of applying a voltage between the first electrode and the second electrode to arrange the fine structures in the fine structure arranging region; and a removing step of removing a fine structure having undesirable arrangement after the fine structure arranging step.

According to the above, the fine structures are arranged as desired, and the fine structure having the undesirable arrangement is removed; the fine structures can substantially be arranged in the desired arrangement.

Further, the present invention provides a method of manufacturing the fine structure arranging substrate which solves the above problem, and in a second embodiment, the method includes a fine structure dispersed solution producing step of dispersing fine structures each having a length of a nano order to a micron order in a solution; a substrate forming step of forming one or more fine structure arranging regions in each of which a first electrode and a second electrode are arranged on an insulating substrate at an interval shorter than the length of the fine structure, and the second electrode is arranged in between the first electrode and a third electrode; an application step of applying the fine structure dispersed solution on the insulating substrate; a fine structure arranging step of applying a voltage between the first electrode and the third electrode to arrange the fine structures in the fine structure arranging region; and a removing voltage applying step of applying a voltage for removing a fine structure having undesirable arrangement to the first electrode or the third electrode after the fine structure arranging step.

According to this, while the fine structures having the desired arrangement can maintain their states, and an appropriate offset voltage range that can remove the fine structures having the undesirable arrangement can be enlarged. Hence, it becomes possible to remove the fine structures having the undesirable arrangement with higher efficiency.

### EFFECTS OF THE INVENTION

According to a semiconductor element of the present invention, there are used the fine structures having the two ends in contact with the aforesaid two electrodes and having the lengths of the nano order to the micron order, and arranged within ±5 degrees with reference to the direction perpendicular to the parallel direction along which the two electrodes are arranged; the performance of the semiconductor element is improved, the variations are decreased, and the yield becomes high.

According to the method of manufacturing the fine structure arranging substrate of the first embodiment of the present invention, since the method includes the removing step of removing the fine structure having the undesirable arrangement after the fine structure arranging step, the fine structure having the undesirable arrangement can exclusively be removed under the state of maintaining the fine structures having the desired arrangement in between the electrodes. As a result, only the fine structures arranged in the desired direction with high control are remained in between the electrodes. The semiconductor element and the display element using the fine structures as the devices can be endowed with high performance and can be manufactured with a satisfying yield.

According to the method of manufacturing the fine structure arranging substrate of the second embodiment of the present invention, the second electrode is disposed between the first electrode and the third electrode, and the voltage is applied between the first electrode and the third electrode, the fine structures are arranged, and then, the voltage to remove the fine structure having the undesirable arrangement is applied to either the first electrode or the third electrode. Thus, while the fine structures having the desired arrangement can maintain their states, and an appropriate offset voltage range that can remove the fine structure having the undesirable arrangement can be enlarged. Hence, it becomes possible to remove the fine structure having the undesirable arrangement with higher efficiency. Accordingly, under a state where the fine structures having the desired arrangement are maintained, the fine structure having the undesirable arrangement can exclusively be removed with higher efficiency. As a result, only the fine structures being arranged in the desired direction with high control are remained in between the electrodes. The semiconductor element and the display element using the fine structures as the devices can be endowed with high performance, and can be manufactured with a satisfying yield.

### BRIEF DESCRIPTION OF THE DRAWINGS

FIG. 1 includes views depicting fine structures used in a semiconductor element of the present invention.

FIG. 2 is a plan view of an insulating substrate used in an embodiment 1 of the present invention.

FIG. 3 is a view explaining procedures by which the fine structures are arranged on the insulating substrate in the embodiment 1 of the present invention.

FIG. 4 is a view explaining a principle of arrangement of fine structures composed of a conductor in the embodiment 1 of the present invention.

FIG. 5 is a view explaining a principle of arrangement of fine structures composed of a dielectric in the embodiment 1 of the present invention.

FIG. 6 includes graphs explaining preferable voltages to be applied to electrodes upon arranging the fine structures in the embodiment 1 of the present invention.

FIG. 7 is a view explaining the procedures by which the fine structures are arranged on the insulating substrate in the embodiment 1 of the present invention.

FIG. 8 is a cross sectional view along line C-D in FIG. 7, explaining a first method of arranging the fine structures on the insulating substrate in the embodiment 1 of the present invention.

FIG. 9 is a plan view of the substrate on which fine structures are arranged in an experiment.

FIG. 10 is a graph showing, for 100 pieces of silicon nanowires that are arbitrarily selected, a distribution of numbers and angles of the silicon nanowires with reference to a direction perpendicular to a direction along which electrodes are formed (a direction shown as X in FIG. 9).

FIG. 11 is a view showing a field effect transistor using the silicon nanowires arranged as shown in FIG. 9.

FIG. 12 is a view showing the fine structures arranged on the insulating substrate in the embodiment 1 of the present invention.

FIG. 13 includes graphs showing an example of voltages in a second method of arranging the fine structures within ±5 degrees in the embodiment 1 of the present invention.

FIG. 14 includes views showing a mechanism of the arrangement of the fine structures in the embodiment 1 of the present invention.

FIG. 15 includes graphs showing an example of voltages in a third method of arranging the fine structures within ±5 degrees in the embodiment 1 of the present invention.

FIG. 16 is a graph showing a relationship between the angle and the number of the fine structures with respect to the direction X before and after an application of an offset voltage in the embodiment 1 of the present invention.

FIG. 17 is a view explaining an insulating substrate used in an embodiment 2 of the present invention.

FIG. 18 is a view explaining a principle of arrangement of fine structures in the embodiment 2 of the present invention.

FIG. 19 includes graphs showing an example of voltages to be applied to electrodes upon arranging the fine structures in the embodiment 2 of the present invention.

FIG. 20 is a view explaining procedures by which the fine structures are arranged on the insulating substrate in the embodiment 2 of the present invention.

FIG. 21 is a view explaining a fourth method of arranging the fine structures on the insulating substrate in the embodiment 2 of the present invention.

FIG. 22 is a view explaining procedures by which the fine structures are arranged on the insulating substrate in the embodiment 2 of the present invention.

FIG. 23 includes graphs showing an example of voltages in a fifth method of arranging the fine structures within ±5 degrees in the embodiment 2 of the present invention.

FIG. 24 includes graphs showing an example of voltages in a sixth method of arranging the fine structures within ±5 degrees in the embodiment 2 of the present invention.

FIG. 25 includes graphs showing an example of voltages in a seventh method of arranging the fine structures within ±5 degrees in the embodiment 2 of the present invention.

FIG. 26 includes graphs showing an example of voltages in an eighth method of arranging the fine structures within ±5 degrees in the embodiment 2 of the present invention.

FIG. 27 is a plan view of an integrated circuit device that is a part of an integrated circuit device according to an embodiment 3 of the present invention.

FIG. 28 is a cross sectional view along line G-H in FIG. 26.

FIG. 29 is a plan view of a display device according to an embodiment 4 of the present invention.

### DESCRIPTION OF REFERENCE SIGNS

1 integrated circuit
2 display element
111, 211 insulating substrate
121, 221 metal electrode (first electrode)
122, 222 metal electrode (second electrode)
130, 231 silicon nanowire
132, 232 silicon nanowire inclinedly arranged
133, 233 silicon nanowire intersectingly arranged
141, 241 IPA
223 metal electrode (third electrode)
337, 338 silicon nanowire
351, 352, 353, 354 metal wiring
361 insulating film
371 interlayer insulating film
381, 382, 383 region
NW fine structure arranging region

### BEST MODE FOR CARRYING OUT THE INVENTION

A semiconductor element according to the present invention includes an insulating substrate on which at least two electrodes are arranged at a predetermined interval and one or more fine structure arranging regions, each of which is formed by a unit of the two electrodes, are formed; a plurality of fine structures each having two ends in contact with the two electrodes and a length of a nano order to a micron order, and arranged within ±5 degrees with reference to a direction perpendicular to a parallel direction along which the two electrodes are arranged; and a semiconductor element electrode in contact with the plurality of the fine structures.

The semiconductor element of the present invention includes the aforesaid features, and may further include in embodiments preferable configurations as described below.

Firstly, the semiconductor element of the present invention further includes a third electrode arranged between the two electrodes. According to this, in the step of arranging the fine structures as desired and in the step of removing the fine structure having undesirable arrangement, patterns of a voltage to be applied to the electrodes are increased, and a larger number of the fine structures having the undesirable arrangement can be removed.

Further, in the semiconductor element of the present invention, the two electrodes are arranged at an interval of 1 μm to 30 μm. According to this, the fine structures can be arranged at desired positions with high efficiency.

Further, in the semiconductor element of the present invention, the plurality of the fine structures arranged between the two electrodes are arranged at substantially even intervals. According to this, performance of the semiconductor is improved, a yield is increased, and variations are suppressed.

Further, in the semiconductor element of the present invention, the interval between the two electrodes is 0.6 to 0.9 times a longitudinal length of the fine structure. According to this, the fine structures can be arranged at the desired positions with higher efficiency.

Further, in the semiconductor element of the present invention, the fine structures are composed of a metal, a semiconductor, or a dielectric, and each have a shape of a wire, a tube, or a quantum wire.

According to this, the fine structures can be selected from a variety of materials and shapes.

Preferably, in the semiconductor element of the present invention, the fine structures are composed of lamination of a metal layer, a semiconductor layer, and a dielectric layer, and each have the shape of the wire, the tube, or the quantum wire.

Further, the semiconductor element of the present invention includes the fine structures each having a laminated structure in which a dielectric layer is laminated on a semiconductor layer, an electrode in contact via the dielectric layer, and an electrode in contact with a semiconductor material with the dielectric layer removed.

According to this, the semiconductor element can be formed using the fine structures.

Further, the semiconductor element of the present invention is obtained by a method of manufacturing a fine structure arranging substrate, including a fine structure dispersed solution producing step of dispersing fine structures each having a length of a nano order to a micron order in a solution; a substrate forming step of forming on an insulating substrate one or more fine structure arranging regions in each of which a first electrode and a second electrode are arranged at an interval shorter than a longitudinal length of the fine structure; an application step of applying the fine structure dispersed solution on the insulating substrate; a fine structure arranging step of applying a voltage between the first electrode and the second electrode to arrange the fine structures in the fine structure arranging region; and a removing step of removing a fine structure having undesirable arrangement after the fine structure arranging step, so that the fine structures are arranged between the first electrode and the second electrode, and there are provided an input electrode and an output electrode that are in contact with the fine structures.

According to this, the semiconductor element can be formed using the fine structures having the desired arrangement, and as a result, the semiconductor element with improved performance, a high yield and small variations can be realized.

The semiconductor element of the present invention is obtained by a method of manufacturing a fine structure arranging substrate, including a fine structure dispersed solution producing step of dispersing fine structures each having a length of a nano order to a micron order in a solution; a substrate forming step of forming on an insulating substrate one or more fine structure arranging regions in each of which a first electrode and a second electrode are arranged at an interval shorter than a longitudinal length of the fine structure, and a third electrode is arranged in between the first electrode and the second electrode; an application step of applying the fine structure dispersed solution on the insulating substrate; a fine structure arranging step of applying a voltage between the first electrode and the second electrode to arrange the fine structures in the fine structure arranging region; and a removing step of applying a voltage for removing a fine structure having undesirable arrangement to the first electrode or the third electrode after the fine structure arranging step, so that the fine structures are arranged between the first electrode and the second electrode, and there are provided an input electrode and an output electrode that are in contact with the fine structures.

According to the above, in the step of arranging the fine structures as desired and in the step of removing the fine structure having the undesirable arrangement, patterns of a voltage to be applied to the electrodes are increased, and a larger number of the fine structures having the undesirable arrangement can be removed.

Further, the semiconductor element of the present invention is capable of easily removing the fine structure having the undesirable arrangement in the removing step including a flowing step of flowing the solution in a direction along which the fine structures are arranged.

Further, in the removing step, a larger number of the fine structures having the undesirable arrangement can be removed by applying an offset voltage to the first electrode, the second electrode, or the third electrode.

Further, in the offset voltage applying step, the offset voltage can alternately be applied to the first electrode, the second electrode, and the third electrode, and thereby a still larger number of the fine structures having the undesirable arrangement can be removed.

Further, an integrated circuit device or a display element of the present invention can be configured by using the semiconductor element described above. According to this, an integrated circuit device having improved performance, a high yield and small variations can be realized.

Further, a first manufacturing method for a fine structure arranging substrate of the present invention is characterized by including a producing step of producing a fine structure dispersed solution by dispersing fine structures each having a length of a nano order to a micron order in a solution; a substrate forming step of forming one or more fine structure arranging regions in each of which a first electrode and a second electrode are arranged on an insulating substrate at an interval shorter than the length of the fine structure; an application step of applying the fine structure dispersed solution on the insulating substrate; a fine structure arranging step of applying a voltage between the first electrode and the second electrode to arrange the fine structures in the fine structure arranging region; and a removing step of removing the fine structure having undesirable arrangement after the fine structure arranging step.

The first manufacturing method for the fine structure arranging substrate of the present invention may have the aforesaid features, and in embodiments, further includes the configuration as described below.

For example, the removing step includes an offset voltage applying step of applying an offset voltage to the first electrode or the second electrode. Moreover, the offset voltage is alternately applied to the first electrode and the second electrode.

According to this, the fine structures having the undesirable arrangement which could not be removed in the offset voltage applying step may be removed.

Further, in the removing step, the AC voltage and the offset voltage are superimposingly applied to the first electrode and the second electrode.

Moreover, the AC voltage and the offset voltage are applied superimposingly and alternately to the first electrode and the second electrode.

According to this, the fine structures having the undesirable arrangement can be removed with higher efficiency.

A second manufacturing method for a fine structure arranging substrate of the present invention includes a removing voltage applying step of applying the voltage for removing the fine structure having the undesirable arrangement to the first electrode or the third electrode after the fine structure arranging step of arranging the third electrode in between the first electrode and the second electrode.

According to this, in the fine structure arranging step and in the removing voltage applying step, flexibility in the patterns of voltage application to the first electrode, the second electrode, and the third electrode is increased.

Further, in the removing voltage applying step of the second manufacturing method, the offset voltage is applied to the first electrode or the third electrode. Alternatively, the offset voltage is applied alternately to the first electrode and the third electrode.

According to this, the fine structures having the undesirable arrangement which could not be removed by the ordinary offset voltage applying step can be removed.

Embodiments of the present invention will be described in detail hereinbelow.

In the present invention, a fine structure is formed in a shape of a nanowire, a nanotube, or a quantum wire, for example. A material therefor is a metal, a semiconductor, a dielectric, or an insulator. Alternatively, the fine structure is composed of any lamination of a metal layer, a semiconductor layer, a dielectric layer, and an insulating layer.

As a material for the semiconductor, silicon, GaAs, GaN, SiC, or a carbon nanotube can be used. As a material for the metal, gold, silver, copper, iron, tungsten, tungsten nitride, aluminum, tantalum, or an alloy thereof, or the like can be used. Further, as the dielectric, a silicon oxide film, a silicon nitride film, a silicon oxynitride film, aluminum oxide, titanic oxide, hafnium oxide, or the like can be used.

The nanowire, the nanotube, or the quantum wire composed of such materials or the lamination thereof is formed. For example, a VLS (Vapor-Liquid-Slid) method is typical for the nanowire and a HiPCO (High Pressure Carbon Monoxide) method is typical for the nanotube, and according to these, a linearly-shaped fine structure having a desired constant length can be fabricated.

According to the VLS method, when the nanowire is grown by silicon depositing at a lower part of gold particles, the nanowire grows while inheriting crystal property of a silicon crystal that is positioned immediately below the nanowire. That is, the nanowire has a crystal orientation toward which it is likely to grow, thus, when a silicon substrate with a crystal orientation perpendicular to a substrate surface thereof is used, the nanowire constantly maintains the crystal property of the silicon substrate, and grows perpendicularly to the substrate surface. By using this method, a linear-shaped fine structure having a constant length can be fabricated. Similarly, by using the HiPCO method, the linear-shaped fine structure having a constant length can be fabricated. Further, by appropriately determining a diameter (tens of μm to a few μm) and the length (a few μm to hundreds of μm) of the fine structure, the linear-shaped fine structure can be fabricated. Furthermore, the linear-shaped fine structure can be fabricated according to the shape of the fine structure such as the nanowire, the nanotube or the quantum wire.

The nanowire, the nanotube, or the quantum wire used in the present invention is not required to have a nano scale for all of the dimensions thereof. For example, a nanowire or a microwire having a diameter of tens of μm to a few μm and a linear length of a few μm to hundreds of μm is included in the fine structure of the present invention. In a case with a stick-shaped fine structure, those having a diameter substantially smaller than 1 μm and a length of tens of μm are referred to. Hence, in the present invention, the fine structures include those of so-called nano orders to micron orders.

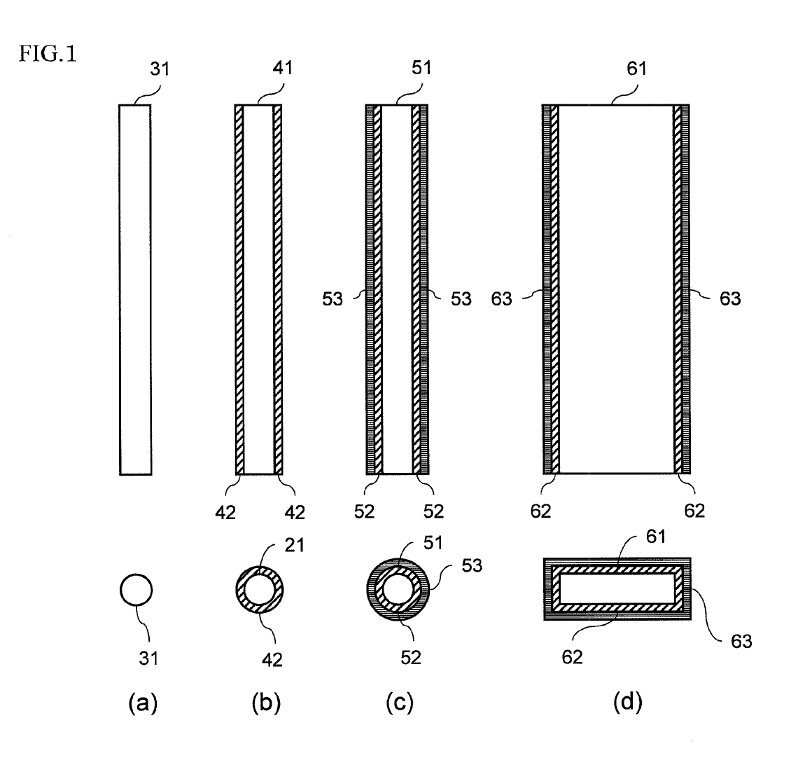

FIG. 1 shows an example of the fine structures. FIG. 1 depicts cross sectional views of a plane including a center line of each fine structure in a longitudinal direction and cross sectional views of a plane perpendicular to the longitudinal direction. FIG. 1(a) shows a single-layered nanowire or nanotube 11. FIG. 1(b) shows a fine structure having a two-layer structure, in which a nanowire or nanotube 21 is coated with an insulator 22. FIG. 1(c) shows an example of a fine structure having a three-layer structure, in which a nanowire or nanotube 31 is coated with an insulator 32, and is further coated with a metal film 33.

The fine structure does not have to be columnar-shaped; as shown in FIG. 1(d), it may have a plate shape. FIG. 1(d) shows an example of a fine structure having a structure in which a plate-shaped conductor 41 is coated with an insulator 42 and a metal film 43. Furthermore, the nanowire or the nanotube may be polygonal, such as triangular, hexagonal, or the like.

The fine structures as described above is preferably linear. By appropriately selecting the materials for the fine structures, conductivity thereof (including a case in which the fine structures themselves are semiconductors), or the structures thereof, a switching element, a light emitting element, or a resisting element can be formed.

In the following description regarding the arrangement of the fine structures, a case of arranging the fine structures having the configuration as shown in FIG. 1(c) will be explained. More specifically, the fine structure is configured such that the nanowire 31 made of silicon is coated with the insulating film 32 composed of a silicon oxide, and is further coated with the metal film 33 composed of TaAlN. This silicon nanowire is preferably linear-shaped. Hereinbelow, this fine structure is referred to as the silicon nanowire.

The silicon nanowire used in the present invention has a diameter of 150 nm and a length of about 25 μm. More specifically, a radius of the nanowire 31 made of silicon is about 45 nm, a film thickness of the insulating film 32 made of the silicon oxide is about 15 nm, and a film thickness of the metal film 33 made of TaAlN is about 15 nm. These values are mere examples, and the present invention is not limited hereto. Furthermore, not all of the silicon nanowires have to have the same size.

Furthermore, in the description regarding an application of the fine structures to devices used in a semiconductor element or a display element, a case of applying the fine structures having the configuration as shown in FIG. 1(b) as the devices will be explained. However, fine structures having the configurations shown in FIG. 1(a) to FIG. 1(d) may be used. More specifically, the fine structure are configured such that the nanowire 21 made of silicon is coated with the insulating film 22 made of silicon oxide. This silicon nanowire is preferably linear-shaped.

A size of the silicon nanowire applied to the semiconductor element or the display element has a diameter of about 120 nm and a length of about 25 μm. More specifically, a radius of the nanowire 21 made of silicon is about 45 nm, and a film thickness of the insulating film 22 made of silicon oxide is about 15 nm. These values are mere examples, and the present invention is not limited hereto.

### Embodiment 1

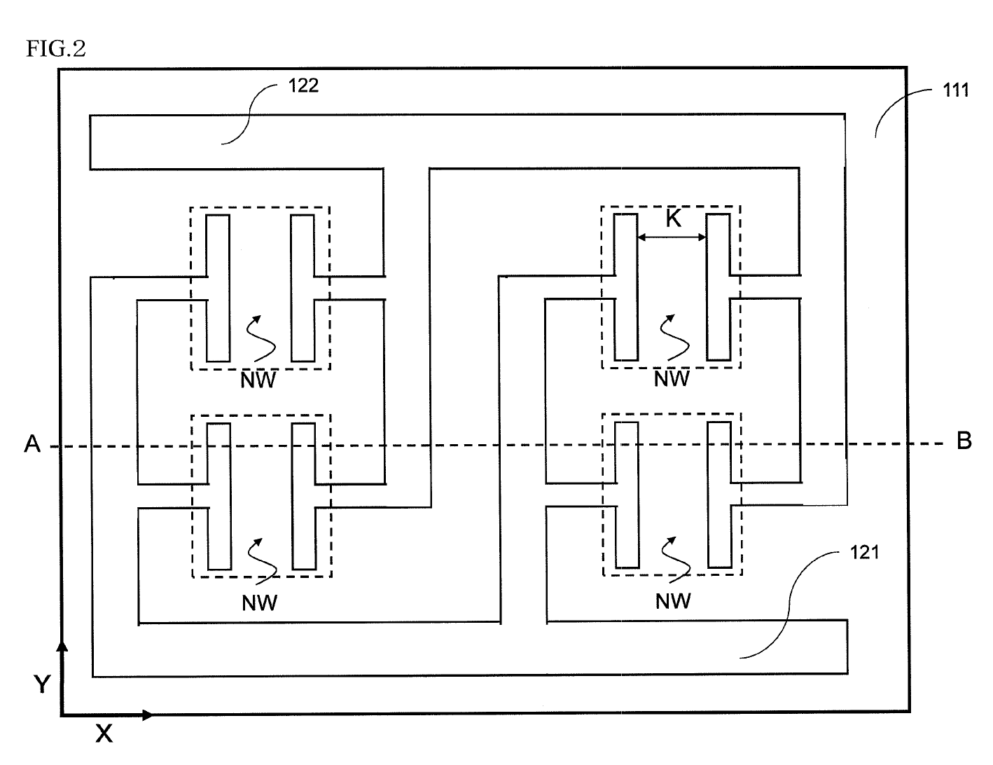

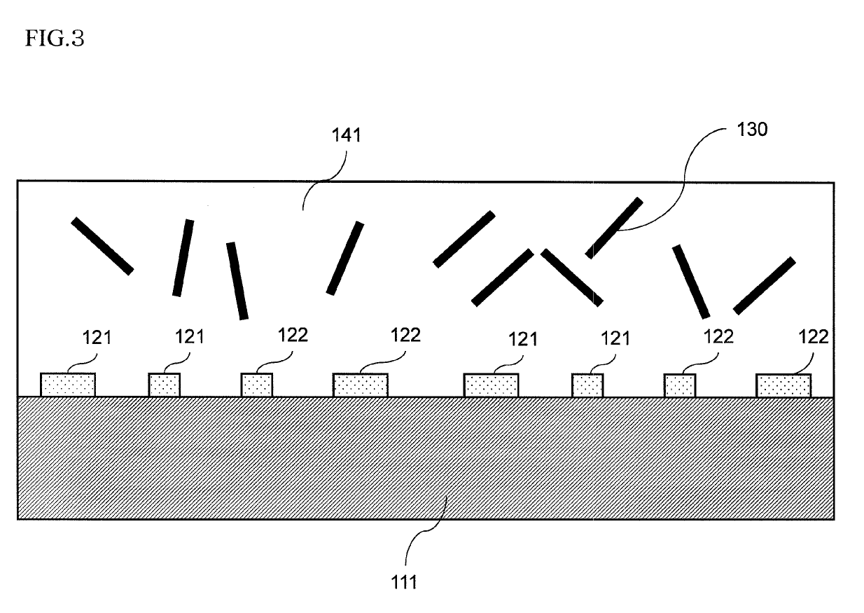

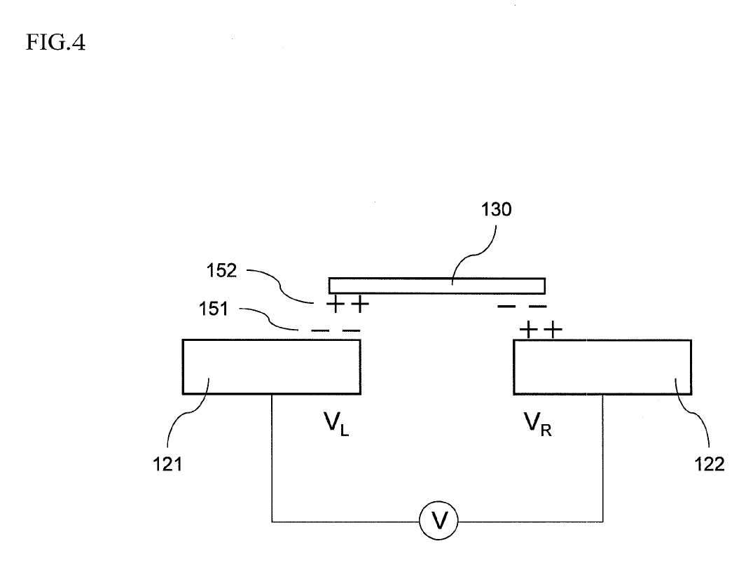

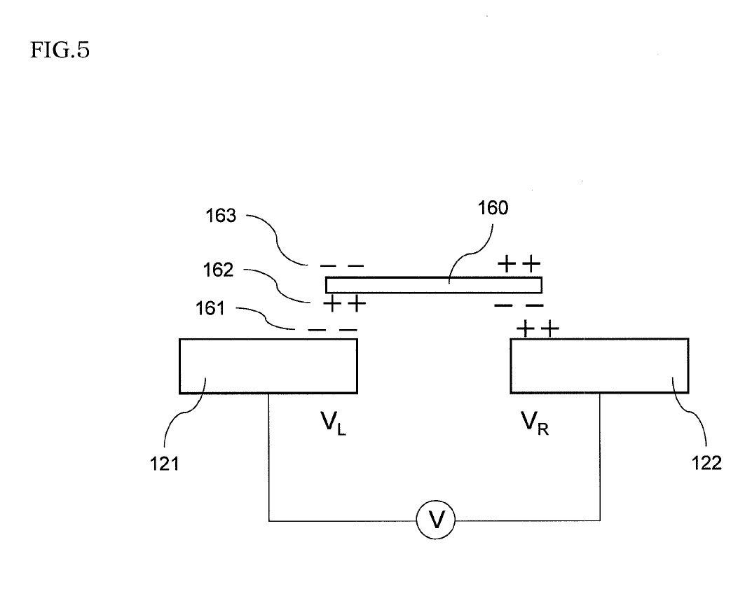

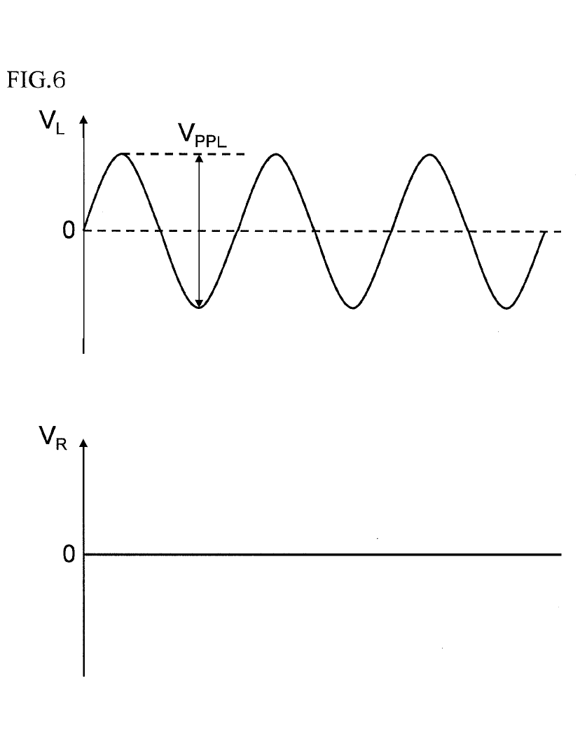

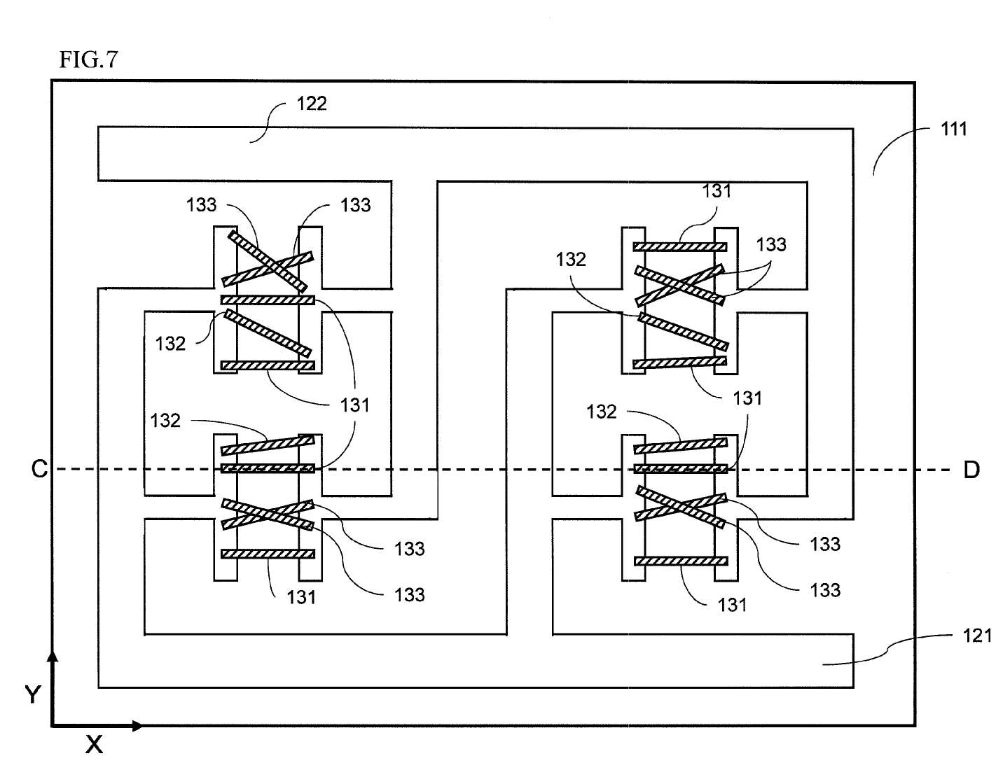

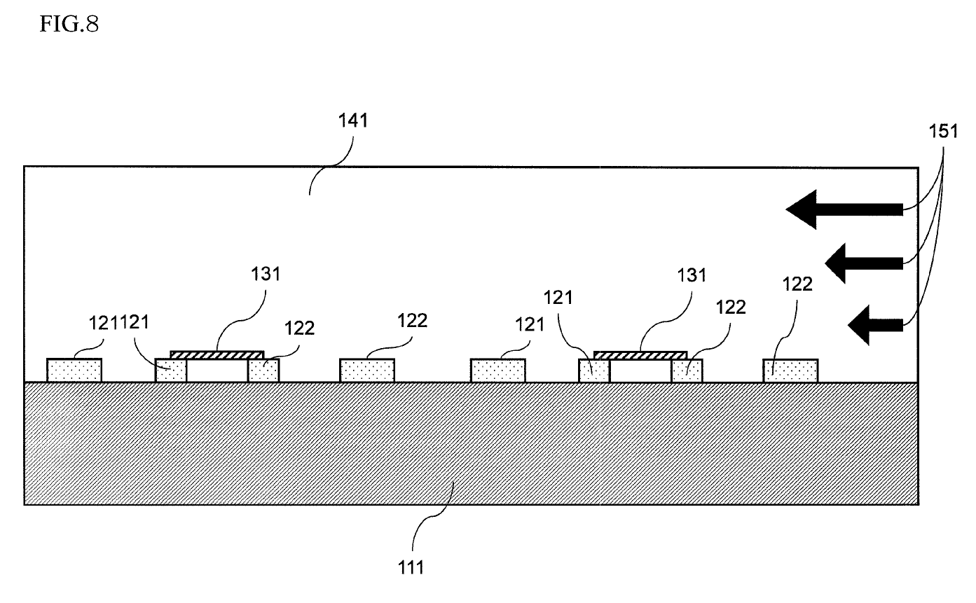

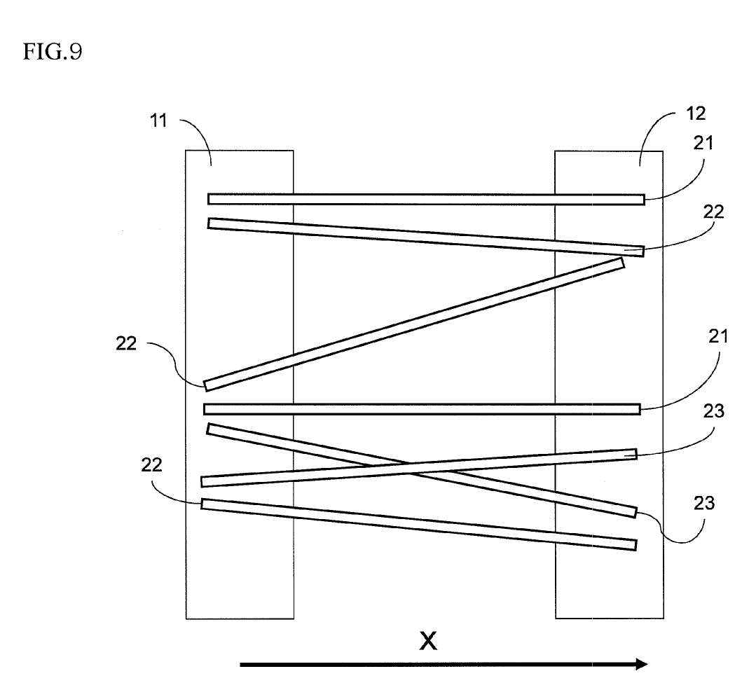

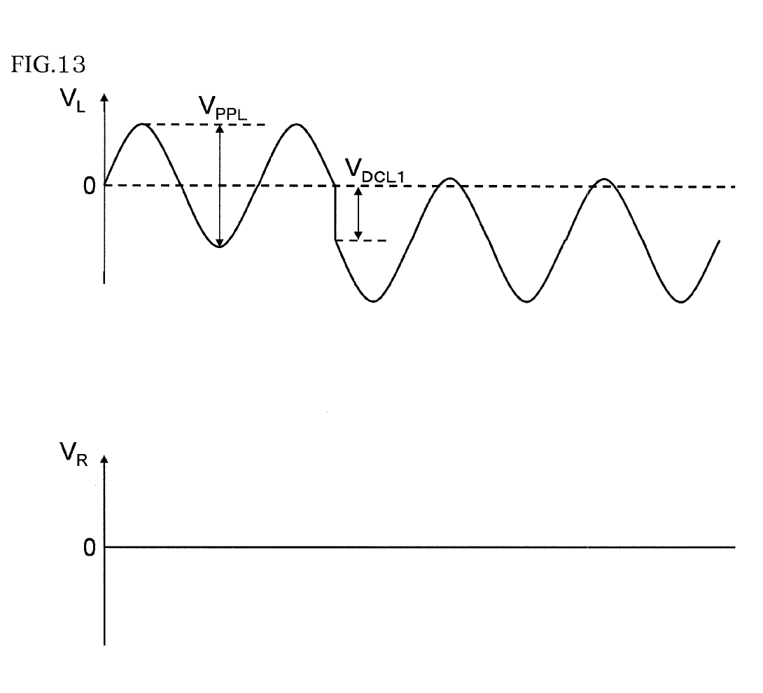

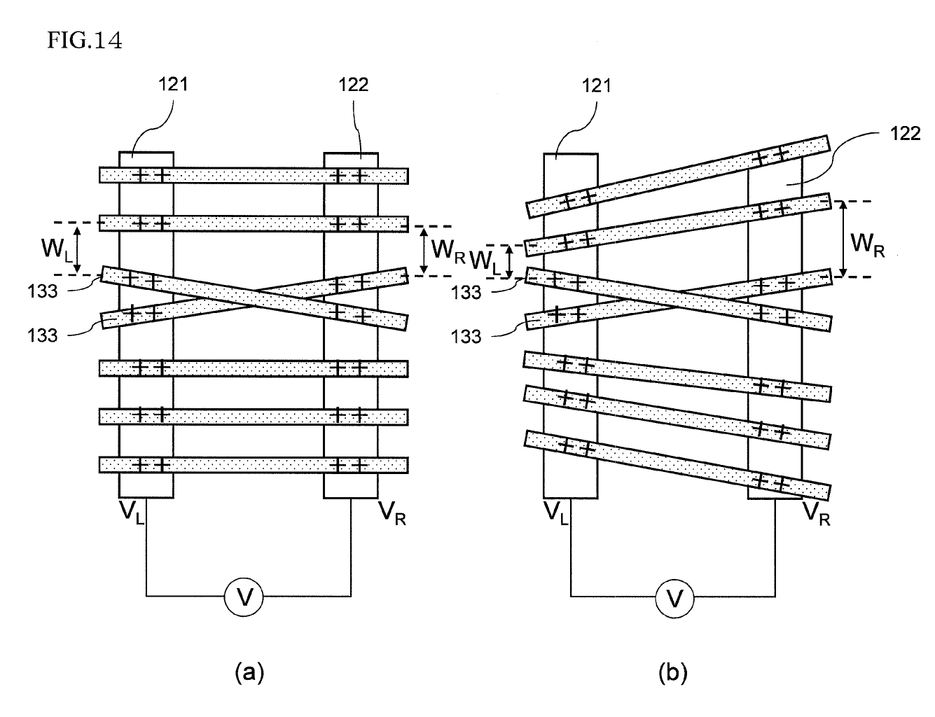

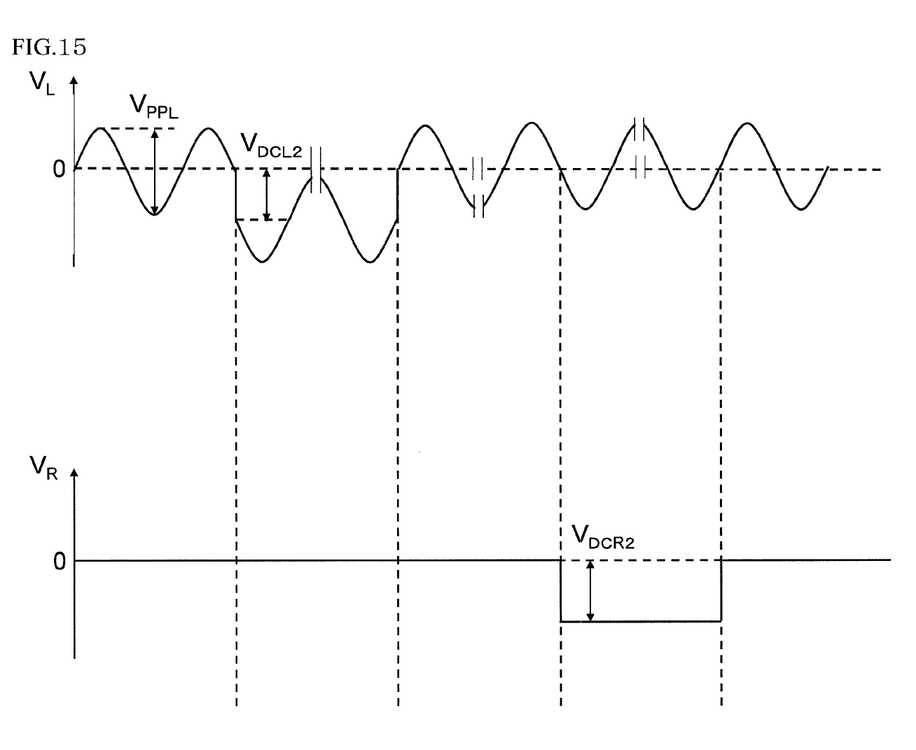

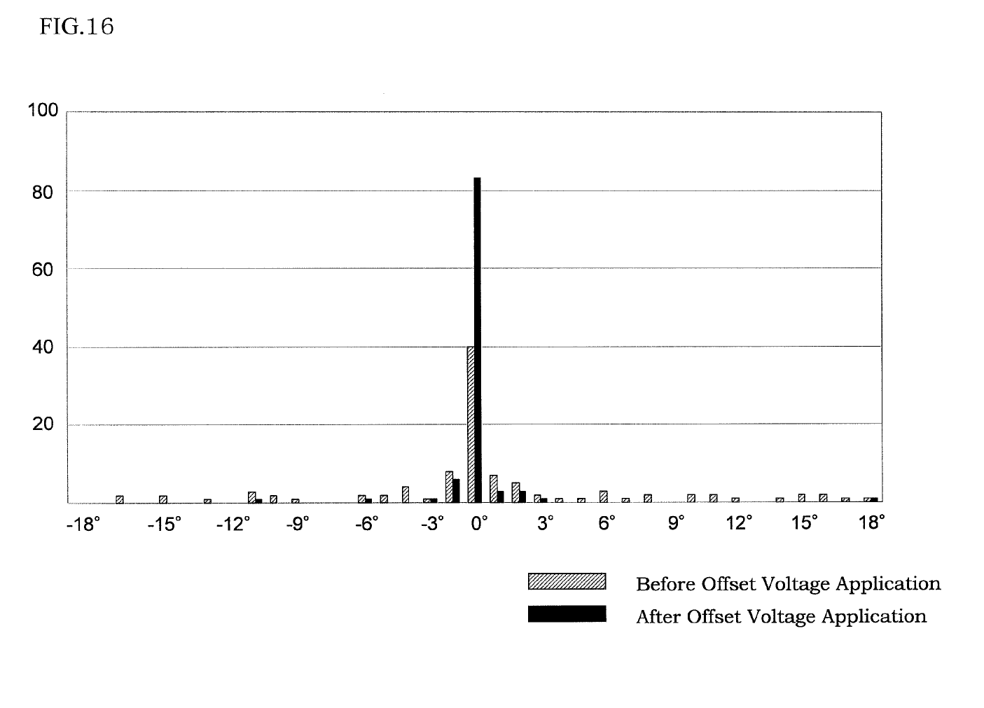

An embodiment 1 of the present invention will be described with reference to FIG. 2 to FIG. 16. FIG. 2 shows an insulating substrate used in the embodiment 1 of the present invention. FIG. 3, FIG. 7, and FIG. 8 explain procedures of a method of arranging fine structures according to the present invention. FIG. 4, FIG. 5, and FIG. 14 explain a principle of an arrangement of the fine structures. FIG. 9 to FIG. 11 explain an experiment according to the present invention. FIG. 6, FIG. 13, and FIG. 15 explain preferable voltages to be applied upon arranging the fine structures. FIG. 16 shows a relationship of an angle and the number of pieces, at which angle with respect to an X direction of 100 pieces of arbitrarily selected silicon nanowires are measured before and after applying an offset voltage.

The insulating substrate onto which the silicon nanowires are arranged is shown in FIG. 2. An insulating substrate 111 is configured such that a silicon oxide film is formed on a surface of an insulator such as a glass, ceramic, alumna or resin, or of a semiconductor such as silicon so as to have an insulating surface. In a case where a glass substrate is used, it is preferable to form a base insulating film such as a silicon oxide film or a silicon nitride film on the surface thereof.

On the surface of the insulating substrate 111, metal electrodes 121, 122 are formed. The metal electrodes 121, 122 can be formed into a desired electrode shape by using a printing technique. Alternatively, they can be formed by uniformly laminating a metal layer and a photoreceptor layer, exposing a desired electrode pattern and, etching.

Although not shown in FIG. 2, the metal electrodes 121, 122 have pads provided therewith such that a voltage may be applied from outside. At portions where the metal electrodes 121, 122 face each other (in FIG. 2, regions framed with a broken line indicated as NW), the silicon nanowires are to be arranged. These regions are referred to as fine structure arranging regions. In FIG. 2, 2×2 pieces of the regions NW where the silicon nanowires are to be arranged are provided, however, one or more arbitrary pieces thereof can of course be arranged.

Here, the two electrodes are formed in parallel, and the fine structures are to be arranged along a direction perpendicular to a direction Y along which the electrodes are formed, which is shown as a direction K in FIG. 2

Note that, a distance K between the metal electrodes 121, 122 in each of the fine structure arranging regions NW is preferably slightly shorter than the linear length of the silicon nanowire. In the experiment of the present invention, the silicon nanowires are substantially linear-shaped, and the length thereof is about 25 μm. As described above, it is preferable for the silicon nanowires to have even lengths and linear property. In this case, when the distance K is determined within 16 to 22 μm, the silicon nanowires could be arranged most effectively. That is, the distance K is preferably set to 60 to 90% of the silicon nanowires; and more preferably, t±80 to 90%. This figure does not represent a size relationship of the electrodes and the silicon nanowires correctly, for the sake of clearer depiction.

Next, the procedure of arranging the silicon nanowires on the insulating substrate 111 is described. Firstly, as shown in FIG. 3 (a cross sectional view along line A-B of FIG. 2), isopropyl alcohol (IPA) 141 in which silicon nanowires 130 are dispersed is thinly applied onto the insulating substrate 111. In substitute of the IPA 141, ethylene glycol, propylene glycol, methanol, ethanol, acetone, or a mixture thereof may be used. Alternatively, in substitute of the IPA 141, a liquid made of another organic compound, or that including water or ions may be utilized. Hence, the IPA 141 may refer to a solution including the silicon nanowires, and is not limited thereto.

A thickness of application of the IPA 141 including the silicon nanowires is to allow the silicon nanowires to move within the liquid so that the silicon nanowires can be arranged in a subsequent step of arranging the silicon nanowires. Hence, the thickness is larger than the diameter of the silicon nanowires, and may be a few μm to a few mm, for example. If the thickness of application is too thin, it becomes difficult for the silicon nanowires to move, and if it is too thick, time required for the liquid to dry is elongated. Preferably, the thickness is 100 μm to 500 μm.

Furthermore, with respect to a quantity of the IPA, a quantity of the silicon nanowires is preferably 1×10⁴ pieces/cm³ to 1×10⁷ pieces/cm³.

In order to apply the IPA 141 including the silicon nanowires, a frame is formed on an outer periphery of the metal electrodes in which the silicon nanowires are to be arranged, and the IPA 141 including the silicon nanowires may be filled inside the frame so as to have a desired thickness. However, in a case where the IPA 141 including the silicon nanowires has a viscosity, it is possible to apply to have the desired thickness without the frame.

For the step of arranging the silicon nanowires, the IPA, ethylene glycol, propylene glycol, or the like, or the mixture thereof, or a liquid made of another organic compound, or a liquid such as water is more preferable to have lower viscosity, and more preferable to easily be evaporated by heating.

Next, a voltage difference is given to the metal electrodes 121 (first electrode), 122 (second electrode). In the embodiment 1, a voltage difference of 1 V was appropriate. 0.1 to 10 V of a voltage difference between the metal electrodes 121, 122 can be applied. The arrangement of the silicon nanowires is degraded at 0.1 V or less, and insulation between the metal electrodes becomes a problem at 10 V or more. Hence, it is preferable to determine at 1 to 5 V, and more preferably, at 1 V.

FIG. 4 indicates the principle of arrangement of the silicon nanowires 130 on the metal electrode 121 (first electrode) and the metal electrode 122 (second electrode). A DC voltage V_{L}, is applied to the metal electrode 121 (first electrode) and a DC voltage V_{R}(V_{L}<V_{R}) is applied to the metal electrode 122 (second electrode). Consequently, a negative charge 151 is induced in the metal electrode 121 (first electrode) and a positive charge is induced in the metal electrode 122 (second electrode), respectively. When the linear-shaped silicon nanowire 130 approaches thereto, a positive charge 152 is induced in the silicon nanowire on a side closer to the metal electrode 121, and a negative charge is induced in the silicon nanowire on a side closer to the metal electrode 122, respectively. The charges are induced in the silicon nanowires due to electrostatic induction. That is, in a conductor disposed in an electric field, charges are induced at a conductor surface until an electric field inside the conductor becomes 0. As a result, an attraction by an electrostatic force works between the respective electrodes and the silicon nanowires, and silicon nanowires 132 are arranged along an electrical flux line that occurs between the metal electrodes 121, 122. Accordingly, the silicon nanowires are arranged in the perpendicular direction X with respect to an electrode forming direction Y.

Furthermore, since the charge induced in each of the silicon nanowires is substantially even, the silicon nanowires may be arranged regularly at even intervals by a repulsive force caused by the charge. Ideally, the charge induced in each of the silicon nanowires is even, however in reality, there may be slight variations. Due to such variations, moving distances of the silicon nanowires, and collisions among the silicon nanowires, the arrangement does not have the even intervals in a strict sense. When being arranged at the even intervals as described above, the silicon nanowires are formed into a single layer.

The silicon nanowires used in this embodiment 1 each have an outermost layer coated with the metal film. However, even in a case of using fine structures composed of a dielectric, they may be arranged on the electrodes according to a similar principle. In the case with the fine structures composed of the dielectric, as shown in FIG. 4, the charge is induced at the surface due to the dielectric polarizing by an external electric field generated between the metal electrodes 121, 122 to which a voltage difference is applied.

In silicon nanowires 160 composed of a dielectric, as shown in FIG. 5, charges are induced. For example, in the vicinity of the metal electrode 121 (having a negative voltage), a positive charge 162 is induced on a side closer to the metal electrode 121, and a negative charge 163 is induced on a side farther away from the metal electrode 121. A negative charge 161 induced in the metal electrode 121 and the positive charge 162 induced in the silicon nanowire 160 are attracted to each other, however, the negative charge 161 induced in the metal electrode 121 and the negative charge 163 induced in the silicon nanowire 160 repulse one another. A similar phenomenon with inverted polarity occurs in the vicinity of the metal electrode 122 (having a positive voltage).

These phenomena occur in a greater extent as being closer to the metal electrodes 121, 122. A force (an attraction force) that works on the positive charge 162 induced in the silicon nanowires is greater than a force (a repulsive force) that works on the negative charge 163. Hence, the attraction force substantially works between the metal electrode 121 and the silicon nanowires 160. The same applies to the force that works between the metal electrode 122 and the silicon nanowires 160.

Due to the reasons above, even in the case where the fine structures composed of the dielectric are used, they can be arranged on the electrodes. Note that, a principle of the dielectric disposed in an inclined electric field to be attracted to the electrodes is described in “Dielectrophoresis, H. A. Pohl, Cambridge University Press, New York, 1978”, for example. Therefore, the material for the fine structures may be any of the metal, the semiconductor, the dielectric, or the lamination thereof.

As stated above, in the present invention, charges are generated on the fine structures by the external electric field that the fine structures have generated between the metal electrodes, and the fine structures are attracted to the metal electrodes by the attraction force of the charges. Thus, the size of the fine structure is required to be of a size capable of moving within a liquid. Therefore, the size of the fine structure may vary in accordance with a quantity (thickness) of the liquid to be applied. If the quantity of the liquid to be applied is small, the fine structures must be of the nano scale, while if the quantity of the liquid to be applied is large, they may be of the micron orders.

In a case where the fine structures are not electrically neutral but are substantially charged positive or negative, the fine structures cannot be arranged stably merely by application of a static voltage difference (DC) between the metal electrodes 121, 122. For example, in a case where the silicon nanowires 130 are substantially charged positive, the attraction force with the electrode 122 to which the positive charge is induced becomes relatively weak. Due to this, the arrangement of the silicon nanowires 130 becomes asymmetric.

In such a case, as shown in FIG. 6, it is preferable to apply an AC between the electrodes 121, 122. In FIG. 6, a reference voltage is applied to the electrode 121, and an AC voltage with an amplitude V_{PPL}/2 is applied to the electrode 122. By doing so, even in the case where the silicon nanowires 130 are substantially charged, the arrangement thereof can be kept symmetric.

Note that, in the embodiment 1 of the present invention, a frequency of the AC voltage applied to the electrode 122 was preferably within 10 Hz to 1 MHz. When the frequency of the AC voltage applied to the electrode 122 is less than 10 Hz, the silicon nanowires 130 are greatly vibrated, and the arrangement frequently is disturbed thereby. On the other hand, when the frequency of the AC voltage applied to the electrode 122 is 1 MHz or more, a force by which the silicon nanowires are attracted to the electrodes becomes weak, and the arrangement is susceptible to being disturbed by an external disturbance. More preferably, the frequency of 50 Hz to 1 kHz most stabilizes the arrangement.

Furthermore, the AC voltage is not limited to a sinusoidal wave; but may be any of a rectangular wave, a triangular wave, a sawtooth wave, or the like, so long as it undergoes a fluctuation periodically. Preferably, the V_{PPL} is set to about 1 V.

As stated above, some time after the silicon nanowires have started to be arranged, the silicon nanowires are arranged as schematically shown in FIG. 7 and FIG. 8. The silicon nanowires are indicated with hatched lines. FIG. 8 is a cross sectional view along line C-D of FIG. 7. In the fine structure arranging region (the region indicated as NW in FIG. 2), the silicon nanowires 130 are arranged along the perpendicular direction X with respect to the electrode forming direction Y substantially at the even intervals. The silicon nanowires are arranged along the perpendicular direction with respect to the electrode forming direction because they align along the electrical flux line by the static force as explained with reference to FIG. 4. Further, the silicon nanowires are arranged substantially at the even intervals because the repulsive force works between the silicon nanowires by the charges induced in the silicon nanowires.

As stated above, ideally, the silicon nanowires 130 are ideally arranged within the fine structure arranging region at the even intervals as one layer along the perpendicular direction (the direction X) with respect to the electrode forming direction. However, in reality, due to the amount of the induced charges, the amount of the movement of the silicon nanowires, the collision between the silicon nanowires, and the like, the desired arrangement cannot be obtained. For example, there exist silicon nanowires 132 that are arranged at angles with respect to the direction X and silicon nanowires 133 that are arranged intersecting one another.

An arrangement of the fine structures experimented by the inventors of the present invention is shown in FIG. 9. In the experiment, as shown in FIG. 9, there are formed two electrodes 11 and 12 on an insulating substrate, applied thereon is a fine structure solution which was dissolved by an organic solvent and dispersed while applying a voltage in between the electrodes, and controlled is the direction of arrangement of the fine structures between the electrodes by removing the solvent. A semiconductor element was formed by using the fine structures having the arrangement controlled as described above.

However, in the experiment, the fine structures were not arranged with sufficient control. Linear silicon nanowires were used as the fine structures, and the silicon nanowires dissolved and dispersed in the organic solvent were applied while applying the AC voltage between the electrodes, and were caused to arrange thereby. As a result, as shown in FIG. 9, the silicon wires 21 are arranged in a direction identical to the perpendicular direction (the direction shown as X in FIG. 9, and hereinbelow referred to as a direction X) with respect to the direction of forming the electrodes 11, 12. However, other than these silicon nanowires 21, as shown in FIG. 9, silicon nanowires 22 arranged at angles with respect to the direction X were observed. Further, as shown in FIG. 9, silicon nanowires 23 arranged at angles with respect to the direction X and intersected one another were also frequently observed.

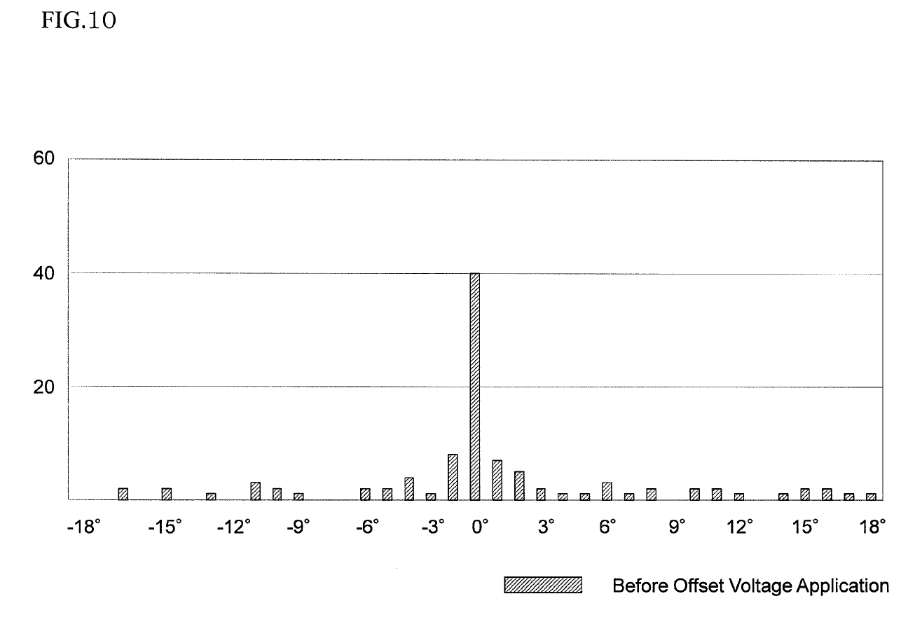

100 pairs of electrodes 11, 12 shown in FIG. 9 were prepared on a glass substrate, and 10 to 20 pieces of silicon nanowires were arranged between the respective pairs of electrodes by the method described above. From among the silicon nanowires arranged between the 100 interelectrode areas, 100 pieces of silicon nanowires were arbitrarily selected, and arrangement angles of the 100 pieces of silicon nanowires were investigated. For the arrangement angles of the silicon nanowires, investigated were an angle distribution of the silicon nanowires with reference to the perpendicular direction (direction X) relative to the electrode forming direction. A result thereof shows, as in FIG. 10, that the silicon nanowires have variations in the angles with respect to the direction X. Specifically, it has been found from the present experimental result that the variations in the angles had a standard deviation of 6.56 degrees.

If the silicon nanowires 22 arranged at the angles as above, or the silicon nanowires 23 intersect one another is fabricated into a semiconductor element, performance and yield are degraded, and the variations are increased.

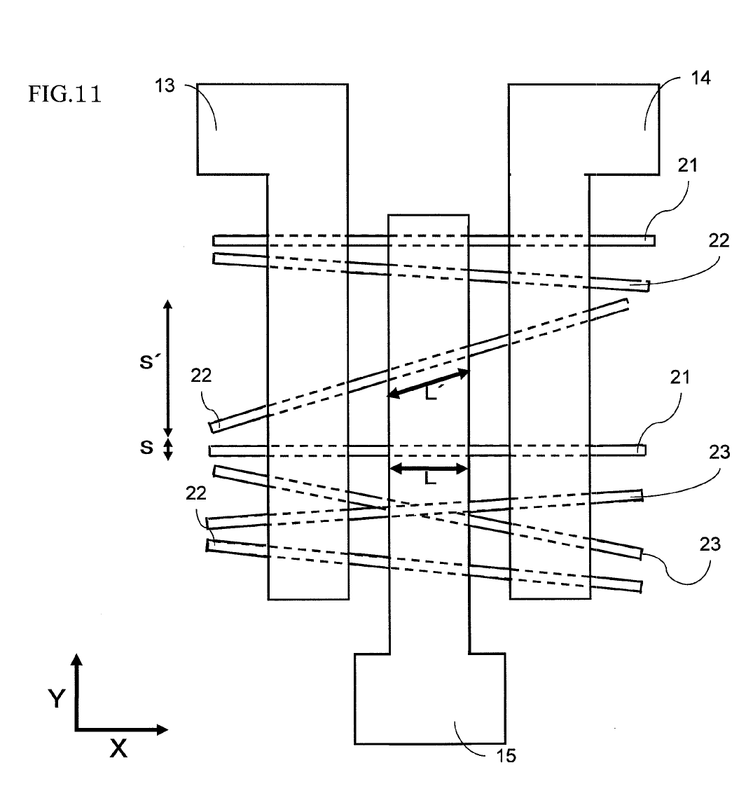

As one specific example, a Metal Oxide Semiconductor Field Effect Transistor (MOSFET) using the silicon nanowires arranged as shown in FIG. 9 is shown in FIG. 11. In FIG. 11, an electrode 13 is a source electrode, an electrode 14 is a drain electrode, and an electrode 15 is a gate electrode. In FIG. 11, a region where the electrode 15 and the silicon nanowires are overlapping forms an effective channel region.

As shown in FIG. 11, between a channel region (L) of a silicon nanowire 21 that is arranged horizontally with respect to the direction X and a channel region (L′) of a silicon nanowire 22 that is arranged at an angle with respect to the direction X, the L′ is longer. Since a MOSFET having a shorter channel length has superior performance, the MOSFET using the silicon nanowires 23 that are arranged at angles has inferior performance compared to those without such angles.

Furthermore, since not all of the silicon nanowires 23 intersecting one another are in contact with one of the above electrodes (in FIG. 11, the source electrode 13 or the drain electrode 14), the function as the MOSFET cannot be obtained, or the performance of the MOSFET is significantly degraded.

Further, in the intersecting silicon nanowires, the silicon nanowire that is arranged on a lower side is hidden by the silicon nanowire that is arranged on an upper side. Due to this, in a subsequent step such as an etching step, the silicon nanowire on the lower side is possibly not being subjected to a desired etching process.

Furthermore, in the silicon nanowires 22 arranged at angles and the silicon nanowires 23 that intersect one another, in comparison to the silicon nanowires 21 that are arranged in a horizontal direction, a width that each silicon nanowire occupies in the electrode forming direction (Y) is larger. As a specific example, a width (S) in the direction Y of the silicon nanowire 21 arranged in the horizontal direction with respect to the direction X is smaller than a width (S′) in the direction Y of the silicon nanowire 22 arranged at an angle.

As stated above, if the widths in the direction Y for respective pieces differ, variations occur in the number of the silicon nanowires to be arranged between electrodes that have even widths in the direction Y. Since the performance of the MOSFET varies according to the number, the variations in the performance of MOSFET are caused thereby. The variations cause a serious obstacle in an industrial application of the MOSFET.

According to the present invention, in light of the above problem and to solve the above problems, the fine structures are arranged horizontally with respect to the direction X. Specifically, the fine structures are required to be arranged within ±5 degrees. A ground of the above condition will be described below.

The silicon nanowires shown in FIG. 11 are exemplary explained. Now, assume that a longitudinal length of the silicon nanowire is 20 μm. Then, in a case of being angled within ±5 degrees with respect to the direction X, it has a width of ±1.75 um in the direction Y. In this case, an interval between adjacent silicon nanowires is from 1 μm to 4 μm, and the silicon nanowires can be arranged at substantially even intervals. Hence, if a silicon nanowire is within ±5 degrees with respect to the direction X, it will be fitted between the adjacent silicon nanowires. Therefore, contacting and intersecting of silicon nanowires can be suppressed. As a result, the silicon nanowires can be formed into one layer.

Presences of the silicon nanowires 22 arranged at angles and the silicon nanowires 23 arranged intersecting one another, as stated above, bring degradation in the performance, the yield, and liability in the semiconductor element production. Hence, in order to arrange the silicon nanowires within ±5 degrees with respect to the direction X, the aforesaid silicon nanowires 22, 23 must be removed.

As a first method therefor, as shown in FIG. 8, while an AC is applied between the metal electrodes 121, 122, the IPA is made to slowly flow in a direction along which the silicon nanowires are arranged (the direction X) (an arrow 151 in FIG. 8).

By controlling a flowing amount and a flow speed of the IPA, the silicon nanowires 132 arranged at angles with respect to the direction X and the silicon nanowires 133 arranged intersecting one another are removed. In this case, it is preferable that the IPA or the application solution does not contain any silicon nanowire.

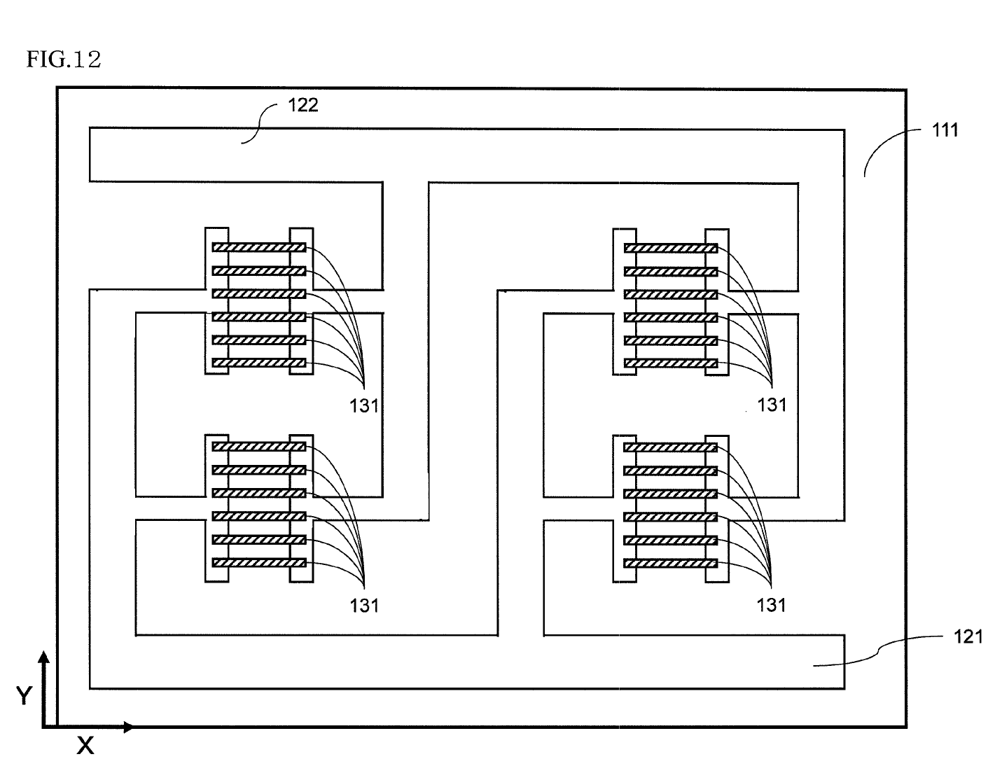

The silicon nanowires 132 arranged at angles with respect to the direction X and the silicon nanowires 133 arranged intersecting one another are, compared to the silicon nanowires 131 arranged horizontally, susceptible to an influence of the flow of the IPA, and are thus preferentially removed thereby. As a result, as schematically shown in FIG. 12, the silicon nanowires 131 arranged horizontally with respect to the direction X are exclusively arranged, and the silicon nanowires are arranged within ±5 degrees with reference to the direction X.

The flowing amount and the flow speed of the IPA are determined such that the silicon nanowires 132 arranged at angles with respect to the direction X and the silicon nanowires 133 arranged intersecting one another are removed, while the silicon nanowires 131 arranged in the direction X are not removed. Further, an inlet opening and an outlet opening for the IPA are preferably apart from the fine structure arranging region. Specifically, in a case where the thickness of the IPA to be applied is 500 μm, it is preferable to cause the IPA to flow at a flow speed of 3 μm/sec to 30 μm/sec, evenly over an entire region where the silicon nanowires are to be arranged. When the flow speed is slower than the above, long time is required for completion of the arrangement, and when the flow speed is faster than the above, the silicon nanowires are yielded to the flow speed and cannot be trapped by the electrodes. The flow speed of the IPA is related to the thickness of the IPA to be applied; if the thickness is increased, the flow speed is increased even when the flow amount is the same.

After the silicon nanowires 131 are arranged between the metal electrodes 121, 122 as described above, then the flow of the IPA and the voltage application are stopped, and the IPA is dried. The IPA can be removed either by heating or vacuum drying. By the aforesaid operations, the silicon nanowires 131 are fixed between the metal electrodes 121, 122.

As a second method, as shown in FIG. 13, to one of the metal electrodes 121, 122, an offset voltage is applied as the application voltage explained above with reference to FIG. 6. An offset voltage herein refers to a voltage applied so as to increase or decrease, by a constant voltage, a voltage applied in the fine structure arranging step.

In FIG. 13, a negative offset voltage (an AC voltage V_{DCL1} herein) is applied only to one metal electrode 121. Due to this, as shown in FIG. 14(b), the silicon nanowires are accumulated toward a center only on the electrode 121; and in accordance with this, observed was a phenomenon in which, in between the electrodes, the silicon nanowires 133 arranged at angles and intersecting one another are snapped out with great impetus and drift about within the IPA. Note that, although the offset voltage (V_{DCL1}) is applied once in FIG. 13, application more than once at a predetermined time interval is preferable.

On the other hand, the silicon nanowires 131 arranged horizontally to the direction X are accumulated toward the center only on the electrode 121, and thereby temporarily are inclinedly arranged to be horizontally asymmetric, however, unlike the case with the silicon nanowires 133 arranged at angles and intersecting one another, the silicon nanowires were not snapped out. It has been confirmed that, thereafter, when the application of the offset voltage is stopped and returned to an original state, the silicon nanowires returned to their desired arrangement. When the V_{PPL} is 1 V, the offset voltage (V_{DCL1}) applies a voltage of about 5 to 20% of the V_{PPL}. Due to this, the silicon nanowires 132 arranged at angles with respect to the direction X and the silicon nanowires 133 intersecting one another could be removed. The offset voltage was, in one example, determined to be V_{DCL1}=−0.12 V.

Although a mechanism by which the silicon nanowires 133 arranged at angles and intersecting one another are removed by applying the offset voltage to one of the first electrode and the second electrode is not clear, an assumed principle of this phenomenon will be described below.

As shown in FIG. 14(a), the silicon nanowires are aligned at the even intervals while repulsing to each other by the charges induced therein, and the intervals of the silicon nanowires in each of the electrodes is identical. Here, in the electrode 121, an interval between the silicon nanowire 131 arranged horizontally to the direction X and the silicon nanowire 133 arranged at an angle and intersecting with another one is assumed as W_{L}. Further, in the electrode 122, an interval between the silicon nanowire 131 arranged horizontally to the direction X and the silicon nanowire 133 arranged at an angle and intersecting with another one is assumed as W_{R}.

In the state of being arranged at the even intervals, by applying the negative offset voltage (V_{DCL1}) to the metal electrode 121, as shown in FIG. 14(b), it has been clarified by observation that the intervals between the silicon nanowires on the side to which the negative voltage was applied becomes narrow. Especially, the interval W_{L} between the silicon nanowire having the desired arrangement and the silicon nanowire having the undesirable arrangement becomes narrow. The interval W_{L} being narrow means that an interval between the charges present in the vicinity of the silicon nanowires becomes narrow coincidentally. Since a repulsive force by charges is proportionate to a square of a reciprocal of a distance, and thus the repulsive force that is generated between the silicon nanowire 131 arranged horizontally to the direction X and the silicon nanowire 133 arranged at an angle and intersecting with another one becomes large.

In this case, among the silicon nanowires 133 arranged at angles and intersecting one another, a silicon nanowire intersects with another silicon nanowire. Thus, unlike the silicon nanowires 131 having a charge distribution arranged horizontally to the direction X, they are assumed to be electrically unstable.

Thus, the repulsive force generated between the silicon nanowire 131 arranged horizontally to the direction X and the silicon nanowire 133 arranged at an angle and intersecting with another one exceeds a force that arranges the silicon nanowires between the electrodes. Due to this, it is assumed that the relatively unstable silicon nanowires 133 arranged at angles and intersecting one another are preferentially snapped out.

Note that in the above example, the offset voltage (V_{DCL1}) is negative, but also in a case of being positive, the silicon nanowires 133 arranged at angles and intersecting one another are removed. In this case, the interval W_{L} between the silicon nanowires disposed above the metal electrode 121 to which the positive offset voltage (V_{DCL1}) has been applied is widened, and interval W_{R} between the silicon nanowires disposed above the metal electrode 122 are narrowed. As a result, the repulsive force is strengthened on the metal electrode 122, and the silicon nanowires 133 arranged at angles and intersecting one another becomes easily separated from the electrodes.

Further, also in regards to the silicon nanowires 132 arranged at angles with respect to the direction X, a similar effect as in the case with the silicon nanowires 133 arranged at angles and intersecting one another was obtained.

From the above description, by applying the offset voltage to one of the electrodes in the state of applying the voltage for causing the arrangement, the silicon nanowires 132 arranged at angles with respect to the direction X and the silicon nanowires 133 arranged at angles and intersecting one another are preferentially removed. Thereby, as schematically shown in FIG. 9, the silicon nanowires 131 arranged horizontally to the direction X are exclusively arranged, and the silicon nanowires are arranged within ±5 degrees with reference to the direction X.

Note that, the offset voltage (V_{DCL1}) to be applied to the metal electrode 121 or the metal electrode 122 needs to have an appropriate magnitude. This is because, if the offset voltage (V_{DCL1}) is too small, the silicon nanowires 133 arranged at angles and intersecting one another cannot be removed. On the contrary, if the offset voltage (V_{DCL1}) is too large, even the silicon nanowires 131 arranged horizontally to the direction X are removed. In the present embodiment, the offset voltage was preferably 0.1 to 0.14 V, which corresponds to 10 to 14% of the voltage V_{PPL} applied to the metal electrodes 121, 122.

In the example of the voltages shown in FIG. 13, the offset voltage was applied to the metal electrode 121 onto which the AC voltage has been applied. Alternatively, the offset voltage may be applied to the metal electrode 122 to which the reference voltage has been applied. Further, although the offset voltage was superimposed to the AC voltage and applied, the offset voltage may be applied after having applied the AC voltage.

Furthermore, when a solution including the silicon nanowires and a small amount of ions is applied to the insulating substrate on which the two electrodes are formed, the silicon nanowires 133 arranged at angles and intersecting one another could be removed with higher efficiency.

As described above, after having arranged the silicon nanowires 131 between the metal electrodes 121, 122, the voltage application is stopped, and the IPA is removed. The IPA can be removed either by heating or vacuum drying. According to the above operations, the silicon nanowires 131 are fixed between the metal electrodes 121, 122.

A third method is characterized in that, as shown in FIG. 15, offset voltages (V_{DCL2}, V_{DCR2}) are alternately applied to the metal electrode 121 and the metal electrode 122. Configurations of the invention other than the above are identical to those of the second method.

By using this method, not only the effect of the second method can be obtained, but also an effect as described below can be obtained.

As confirmed in an experiment, by using the third method of applying not only the offset voltage V_{DCR1} to the metal electrode 121 but also the offset voltage V_{DCR2} to the metal electrode 122, the silicon nanowires 133 arranged at angles and intersecting one another, which could not have been removed by the second method, can be removed.

An experiment result obtained by using the third method is shown in FIG. 16. Details of the experiment is that, as shown in FIG. 5, on a glass substrate onto which 10×10 pieces of the fine structure arranging regions NW for arranging the silicon nanowires were arranged, and 10 to 20 pieces of silicon nanowires were arranged on each of the fine structure arranging regions. In this state, 100 pieces of silicon nanowires were arbitrarily selected, and investigated were angles of the silicon nanowires with respect to the direction X of the respective electrodes and the number thereof before and after the application of the offset voltage. FIG. 16 shows the angles and a distribution of the number silicon nanowires.

As shown in FIG. 16, before the application of the offset voltage, the number of silicon nanowires existing at angles within ±5 degrees with respect to the direction X was 73 out of 100 pieces. On the other hand, after the application of the offset voltage, the number of the silicon nanowires was 98 out of 100 pieces. Further, the standard deviation is changed from 6.56 degrees to 2.16 degrees, and the variations thereof are significantly reduced.

This mechanism may be recognized as described below. The silicon nanowires 133 arranged at angles and intersecting one another are not necessarily horizontally symmetric. This is due to the fact that the silicon nanowires intersect one another in a wide variety of manners. That is, there is a difference between a charge distribution in the metal electrode 121 and a charge distribution in the metal electrode 122, and thereby a magnitude of the repulsive force caused by the charges due to applying the offset voltage to one side may differ between the left side and the right side. Thus, by applying the offset voltage to each of the sides alternately, the silicon nanowires that were not removed by the offset voltage only on one side can be removed.

According to the above, by alternately applying the offset voltage, the silicon nanowires 133 arranged at angles and intersecting one another can be removed more effectively. As a result, as schematically shown in FIG. 12, the silicon nanowires 131 arranged horizontally to the direction X are exclusively arranged, and the silicon nanowires are arranged within ±5 degrees with reference to the direction X.

Note that, in the example of the voltages shown in FIG. 15, the offset voltage was applied once to the metal electrodes 121 and 122, however, it is preferable to apply more than once at a predetermined time interval. Further, although the offset voltage was applied by superimposing to the AC voltage, the offset voltage may be applied after application of the AC voltage. Moreover, although the time to apply the offset voltage in the example of FIG. 15 corresponds to two AC cycles, a length of the cycle can be determined arbitrarily.

According the above, after the silicon nanowires 131 are arranged between the metal electrodes 121, 122, the voltage application is stopped, and then the IPA is dried. The IPA can be removed either by heating or vacuum drying. By the aforesaid operations, the silicon nanowires 131 are fixed between the metal electrodes 121, 122.

### Embodiment 2

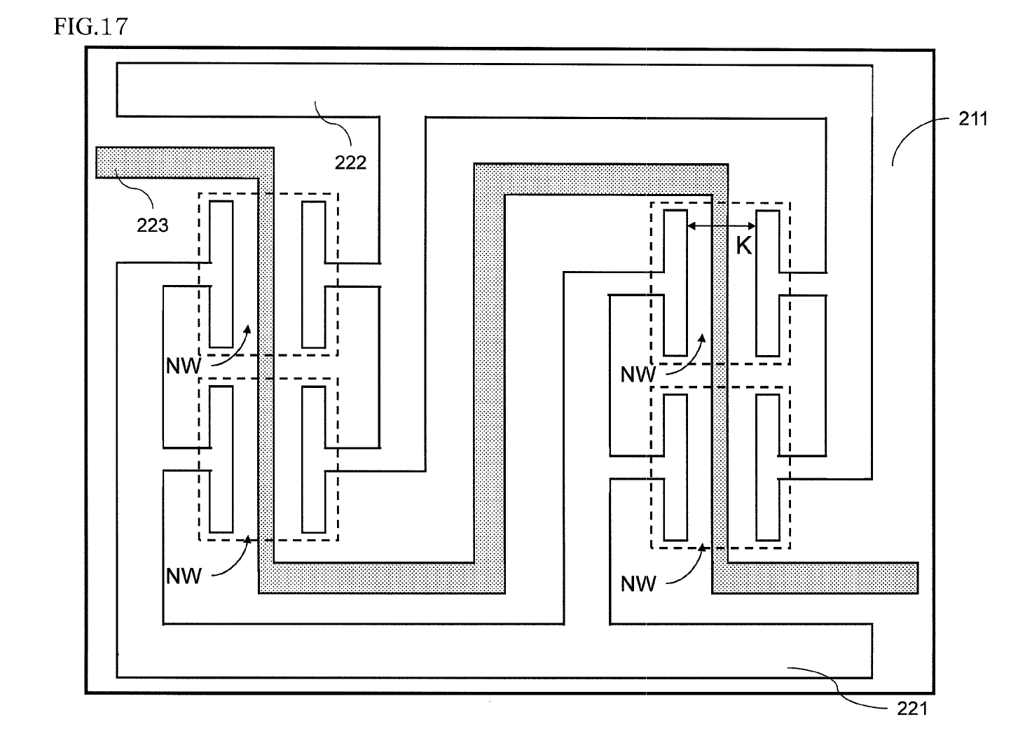

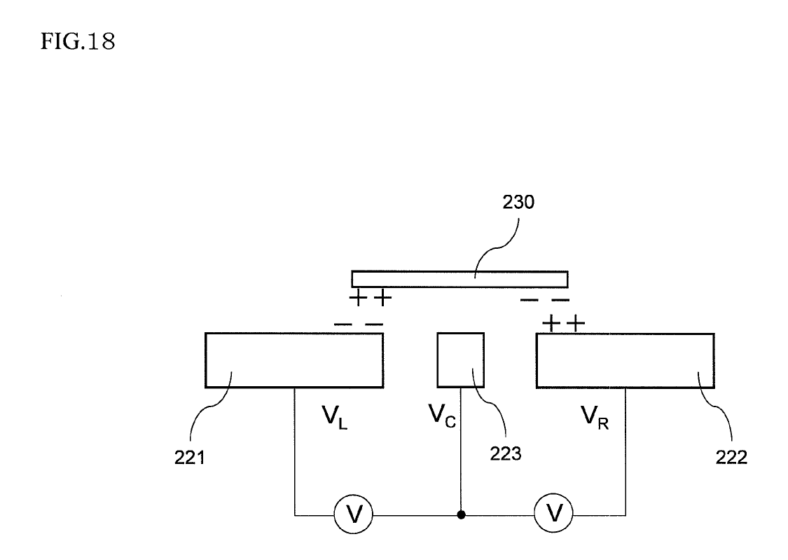

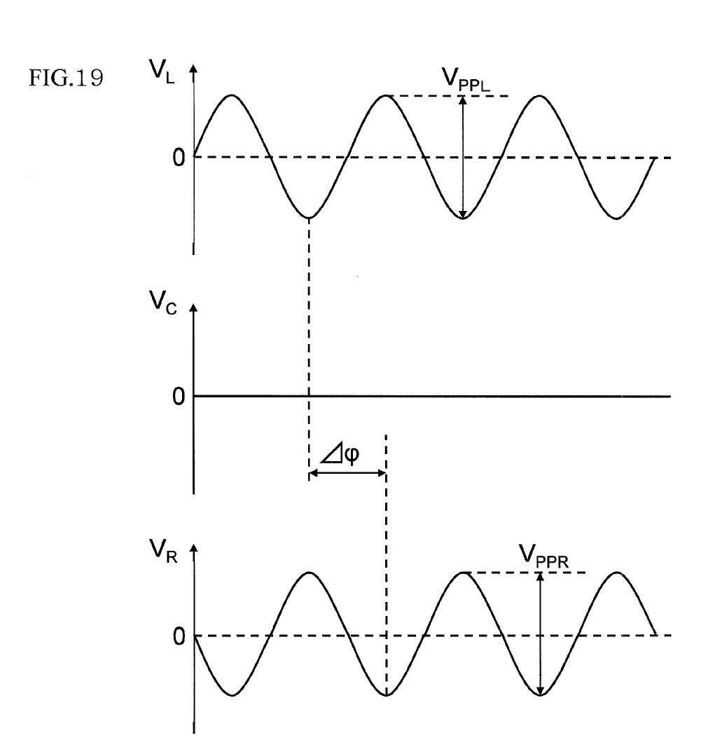

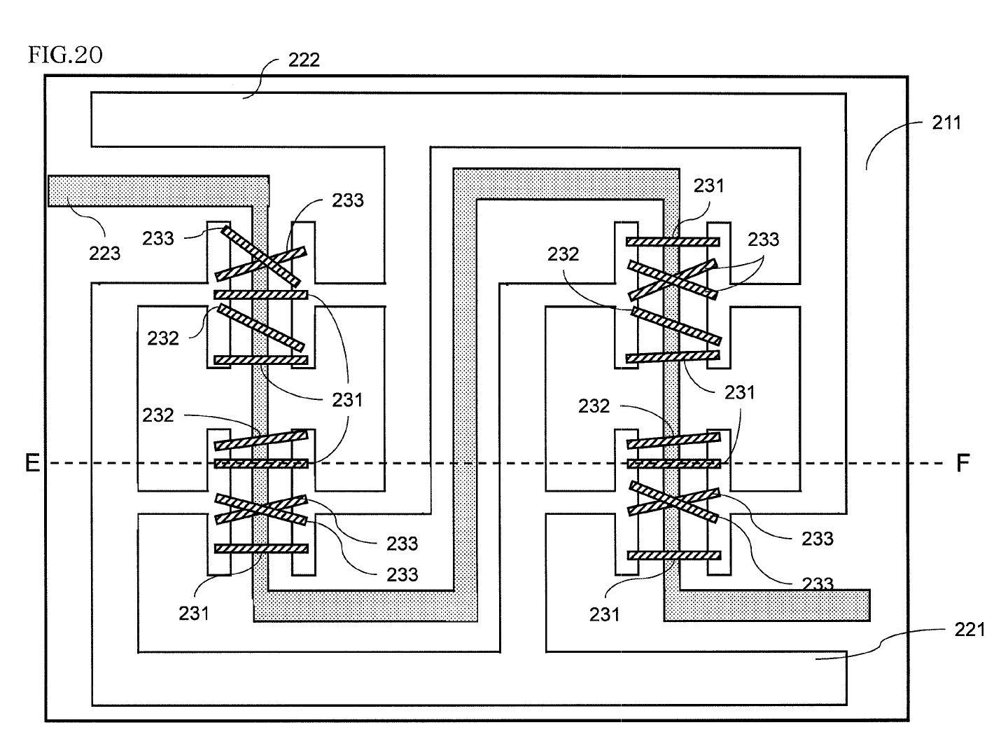

The present embodiment will be explained with reference to FIGS. 17 to 26. FIG. 17 shows an insulating substrate used in the present embodiment. FIG. 18 is a view for explaining a principle of the arrangement of the fine structures. FIG. 19 and FIGS. 23 to 26 are graphs showing preferable voltages to apply to electrodes upon arranging the fine structures. FIGS. 20 to 22 are views for explaining procedures in a method of arranging the fine structures.

The embodiment 2 is characterized by using the insulating substrate onto which more than one fine structure arranging region is formed by a unit of three electrodes, to each of which voltage application can be performed independently from one another. The three electrodes include a first electrode, a second electrode, and a third electrode that are orderly aligned. A voltage is applied to each of the three electrodes, and a fine structure solution in which the fine structures of nano orders to micron orders are dispersed is applied. After this fine structure arranging step, there is included a step of removing a fine structure having undesirable arrangement. Due to this, the fine structures are arranged in a perpendicular direction with respect to the electrode forming direction, and the fine structures are arranged within ±5 degrees with reference to the perpendicular direction. Semiconductor electrodes are brought into contact with the fine structures arranged as above. Details thereof will be described hereinbelow with reference to the drawings. Matters to which specific explanation is not made are identical to those of the embodiment 1.

FIG. 17 shows the insulating substrate having silicon nanowires arranged. On a surface of an insulating substrate 211, metal electrodes 221, 222, 223 are formed. Although not shown in FIG. 17, the metal electrodes 221, 222, 223 are each provided with a pad so that a voltage can be applied from outside. The silicon nanowires are to be arranged in a portion where the metal electrodes 221, 222 face each other (in FIG. 17, a fine structure arranging region NW). This region is referred to as the fine structure arranging region.

Being different from the embodiment 1, the present embodiment 2 is provided with the metal electrode 223 in between the metal electrodes 221, 222. That is, in the fine structure arranging region NW, three electrodes are aligned in an order of the metal electrode 221 (first electrode), the metal electrode 223 (third electrode), and the metal electrode 222 (second electrode). In other words, in the fine structure arranging region, the third electrode passes in between the first electrode and the second electrode. Furthermore, regardless of the fine structure arranging region or not, the third electrode extendingly resides between the first electrode and the second electrode. The metal electrode 223 (third electrode) may be at a midst of the metal electrode 221 (first electrode) and the metal electrode 222 (second electrode), but alternatively may be disposed closer to one of the metal electrode 221 (first electrode) and the metal electrode 222 (second electrode). In FIG. 17, although 2×2 pieces of the fine structure arranging regions NW are disposed, of course one or more arbitrary number of pieces may arbitrarily be disposed.

The configurations of and the forming methods for the insulating substrate 211 and the metal electrodes 221, 222, 223 are identical to those described in the embodiment 1. Although the metal electrode 223 shown in FIG. 17 has a pattern, which does not have a specific meaning but is intended merely for clearer depiction.

Note that a distance K between the metal electrodes 221, 222 is preferably slightly shorter than a longitudinal length of the silicon nanowire. In an experiment conducted in the present embodiment, the silicon nanowire was substantially linear-shaped, and the length thereof was about 25 μm. In this case, the distance K set to 16 to 22 μm allowed most efficient arrangement of the silicon nanowires. That is, the distance K preferably is about 60 to 90% of the silicon nanowire, and more preferably, 80 to 90% thereof.

Next, onto the insulating substrate 211, an IPA in which the silicon nanowires are dispersed is thinly applied. Instead of the IPA, a liquid composed of another organic compound or water may be used. Further, the liquid may contain ions.

Next, voltages are applied to the metal electrodes 211, 222, 223. The present embodiment is different from the embodiment 1 in that, since there are provided three electrodes, flexibility in the voltage application is significantly increased. Therefore, as stated below, the arrangement of the silicon nanowires can greatly be improved.

FIG. 18 shows a principle of the arrangement of the fine structures. Due to charges induced in the metal electrodes 221, 222 (to which voltages V_{L}, V_{R} are applied respectively) being attracted to charges induced in the silicon nanowires, the silicon nanowires 230 are arranged. In this respect, the principle of the arrangement of the silicon nanowires is identical to that in the above embodiment 1 (with two electrodes). That is, the metal electrodes 221, 222 of the present embodiment 2 correspond to the metal electrodes 121, 122 of the embodiment 1. In the present embodiment 2, in addition thereto, a voltage V_{C} can be applied independently to the metal electrode 223. Examples of the favorable voltages to be applied between the metal electrodes 221, 222, 223 will be described below.

One example of the favorable voltages is shown in FIG. 19. A reference voltage is applied to the metal electrode 223 (third electrode), and an AC voltage is applied to each of the metal electrode 221 (first electrode) and the metal electrode 222 (second electrode). By applying the AC voltages as above, even in a case where the fine structures are not electrically neutral but are substantially charged positive or negative, the fine structures can be stably arranged.

Favorable frequencies are, similarly to the case of the embodiment 1, preferably 10 Hz to 1 MHz, and more preferably 50 Hz to 1 kHz. The reason therefor is as explained in the embodiment 1. A difference between the voltage applied to the metal electrode 223 and the voltages to be applied to the metal electrode 221 and 222 is preferably 0.1 V to 10 V. If the difference is 0.1 V or less, the arrangement of the silicon nanowires is degraded, and if the difference is 10 V or more, an insulation between the metal electrodes becomes problematic. Therefore, the difference is preferably 1 to 5 V, and more preferably about 1 V.

The AC voltages applied to the metal electrodes 221 and 222 have the same frequency, and preferably have a phase difference (Δφ) of 150° to 210°. FIG. 19 shows a case of having the phase difference of 180°. In the example of FIG. 19, amplitudes of the AC voltages applied to the metal electrodes 221 and 222 are V_{PPL}/2 and V_{PPR}/2, respectively.

However, a relative voltage imposed on the metal electrodes 221 and 222 is V_{PPL}/2+V_{PPR}/2. In a case of V_{PPL}=V_{PPR}, V_{PPL}/2+V_{PPR}/2=V_{PPL} is established; thus, the substantial voltage difference becomes doubled. That is, even if the amplitudes of the AC voltages applied to the metal electrodes 221 and 222 are halved (½), a magnitude of the electric field required for the arrangement can be secured.

Further, since the effective voltage difference is doubled, amounts of the charges excited on a surface are doubled accordingly. As a result, a repulsive force between the adjacent fine structures acts stronger, and thereby fine structures can be arranged at further improved even intervals compared to the embodiment 1.

On the other hand, since the voltage applied to each of the electrodes is halved (½), silicon nanowires that are attracted to parts other than the fine structure arranging regions (the portions indicated as NW in FIG. 17) can be significantly decreased. The phase difference Δφ does not necessarily have to be 180°; and a sufficient effect can be achieved so long as within the range of 150° to 210°.

As stated above, by applying the example of the voltages shown in FIG. 19, a wide range of voltage values can be set. Further, a larger number of the silicon nanowires can be arranged in the perpendicular direction with respect to the electrode forming direction at the even intervals.

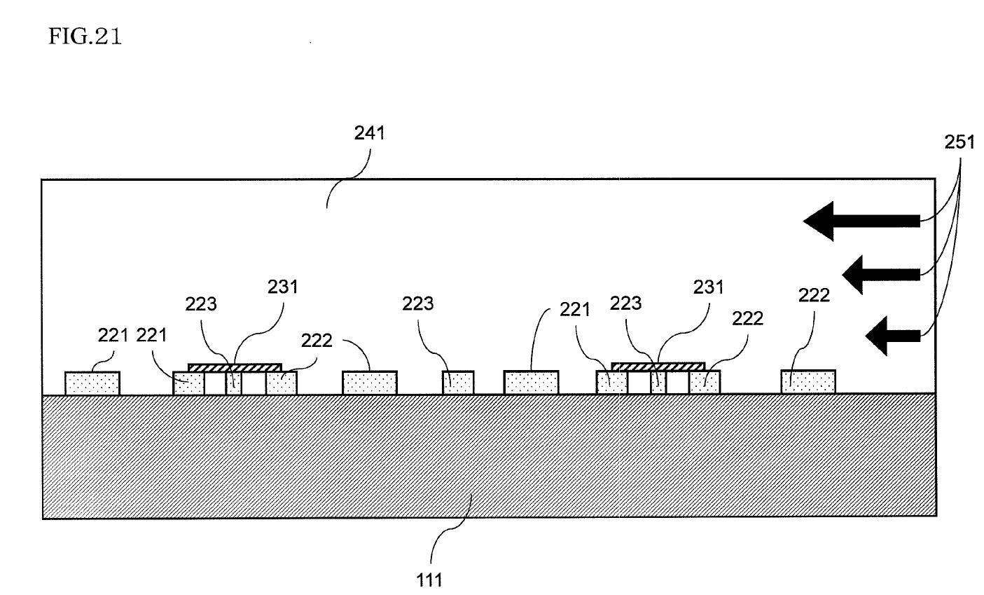

The silicon nanowires were arranged as schematically shown in FIG. 20 and FIG. 21. FIG. 21 is a cross sectional view along line E-F in FIG. 20.

The silicon nanowires 230 were arranged within the fine structure arranging region in three types: silicon nanowires 231 arranged horizontally to a direction X; silicon nanowires 232 arranged at angles with respect to the direction X; and silicon nanowires 233 arranged intersecting one another. The presences of the silicon nanowires 232 arranged at angles with respect to the direction X and the silicon nanowires 233 arranged intersecting one another decrease the performance and a yield of the semiconductor element, and degrades the liability thereof as described earlier in the section of the problems to be solved by the invention. Accordingly, in order to arrange the silicon nanowires within ±5 degrees with respect to the direction X, the aforesaid silicon nanowires 232, 233 must be removed.

As a fourth method therefor, as shown in FIG. 21, while applying the AC between the metal electrodes 221, 222, the IPA is made to flow slowly in a direction along which the silicon nanowires are arranged (i.e., the direction X) (see an arrow 251 in FIG. 21).

By controlling a flowing amount and a flow speed of the IPA, the silicon nanowires 232 arranged at angles with respect to the direction X and the silicon nanowires 233 arranged intersecting one another can be removed. In this case, it is preferable that the IPA or the application solution does not contain any silicon nanowire.

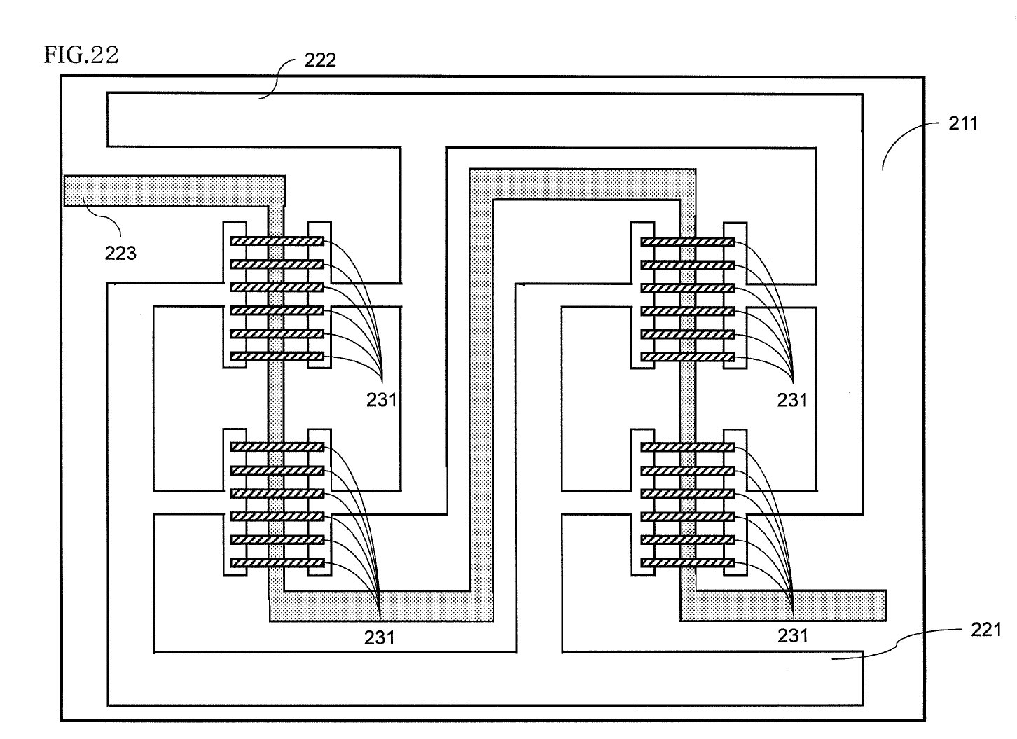

The process in which the silicon nanowires 232 arranged at angles with respect to the direction X and the silicon nanowires 233 arranged intersecting one another are removed is similar to that of the above first method. The flowing amount and the flow speed of the IPA may be set similarly to the above first method. As a result, as schematically shown in FIG. 22, the silicon nanowires 231 arranged horizontally to the direction X are exclusively arranged, and the silicon nanowires are arranged within ±5 degrees with reference to the direction X.

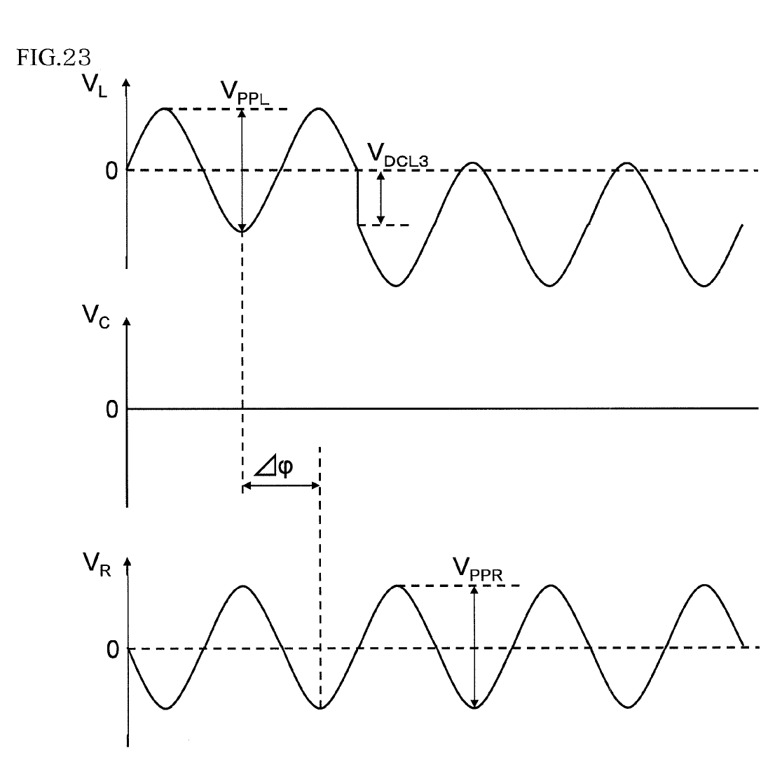

A fifth method as shown in FIG. 23, is a method of applying the offset voltage to one of the metal electrode 221 and 222 with the above applied voltage as the reference.

In the example of the voltages in FIG. 23, a negative offset voltage (a DC voltage V_{DCL3} herein) is applied only to the metal electrode 221 on one side. Consequently, similarly to the above second method, a phenomenon in which the silicon nanowires 233 arranged at angles and intersecting one another are snapped out with a great impetus and drift about in the IPA was observed. Although the offset voltage (V_{DCL3}) is applied once according to FIG. 23, it is preferable to apply more than once at a predetermined time interval. Further, although the offset voltage was superimposed to the AC voltage and applied, the offset voltage may be applied independently after having applied the AC voltage.

On the other hand, the silicon nanowires 231 arranged horizontally to the direction X are accumulated toward the center only on the electrode 221, and thereby temporarily are inclinedly arranged to be horizontally asymmetric, however, unlike the case with the silicon nanowires 233 arranged at angles and intersecting one another, the silicon nanowires were not snapped out. It has been confirmed that, thereafter, when the application of the offset voltage is stopped and returned to an original state, the silicon nanowires were rearranged horizontally. The present embodiment applies V_{DCL3}=−0.2 V.

Thereafter, the voltage application is stopped, and the IPA is dried and removed. According to this, the silicon nanowires are fixed to the metal electrodes 221, 222, 223.

Further, by using the three electrodes, there is an advantage that an application range of the offset voltage to be applied is widened compared to the embodiment 1 utilizing two electrodes. This is because, in the case of having three electrodes, the magnitude of the electric field imposed between the electrodes in the embodiment 2 is larger than the case with two electrodes. As a result, the force to attract the silicon nanowires is increased. Thus, the application range of the offset voltage to perform the removal is widened. In this embodiment 2, it was appropriate to determine the voltage at an absolute of 0.14 to 0.29 V.

Further, also in regards to the silicon nanowires 232 arranged at angles with respect to the direction X, there was obtained a similar effect as in the case with the silicon nanowires 233 arranged at angles and intersecting one another.

According to the above, by applying the offset voltage to one of the electrodes in the state of applying the voltage for causing the arrangement, the silicon nanowires 232 arranged at angles with respect to the direction X and the silicon nanowires 233 arranged at angles and intersecting one another are preferentially removed. As a result, as schematically shown in FIG. 22, only the silicon nanowires 231 arranged horizontally to the direction X are arranged, and the silicon nanowires are arranged within ±5 degrees with reference to the direction X.

Further, when a solution containing the silicon nanowires and a small amount of ions is applied to the insulating substrate on which the three electrodes are formed, the silicon nanowires 233 arranged at angles and intersecting one another were able to be removed with higher efficiency.

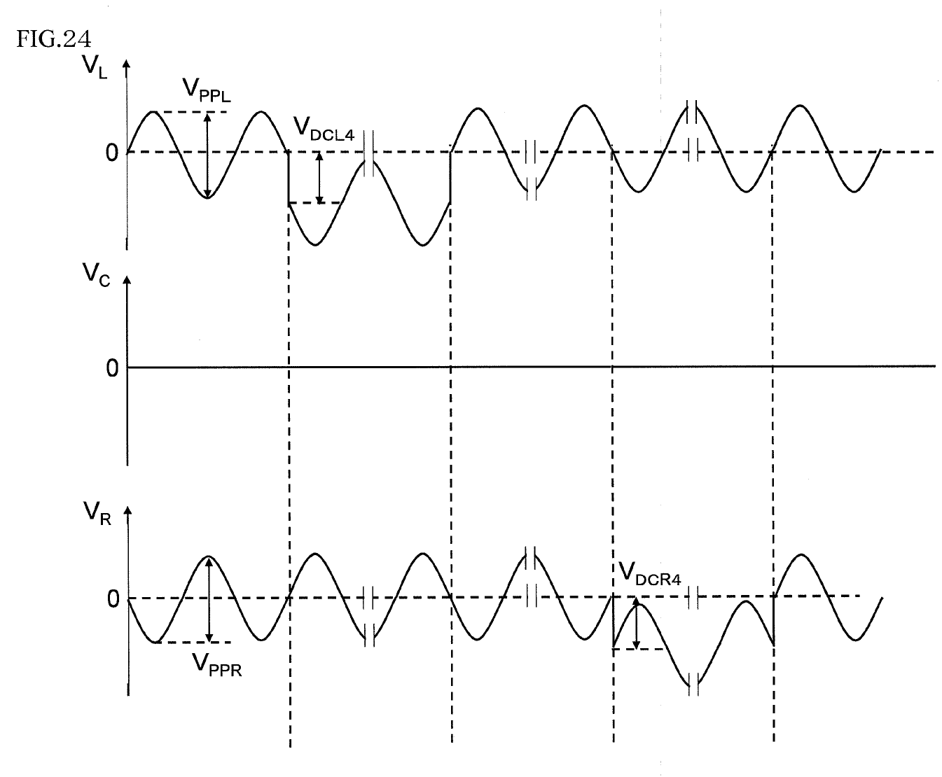

In a sixth method as shown in FIG. 24, offset voltages (V_{DCL4}, V_{DCR4}) are applied alternately to the metal electrode 221 and the metal electrode 222. Note that the offset voltages (V_{DCL4}, V_{DCR4}) are preferably applied more than once at a predetermined time interval. Furthermore, the offset voltages may be applied after having applied an AC voltage. Although application time of the offset voltages in FIG. 24 corresponds to one and a half cycle of the AC, it may alternatively be one cycle or two cycles; it may be set arbitrarily.

By using this method, there are obtained the effect by the fifth method, as well as an effect described below.

By an experiment, is has been confirmed that by using the sixth method in which not only the offset voltage V_{DCL4} is applied to the metal electrode 221 but also the offset voltage V_{DCR4} is applied to the metal electrode 222 alternately, the silicon nanowires 233 arranged at angles and intersecting one another, which could not have been removed by the fifth method, can be removed. The mechanism is as explained earlier in the embodiment 1.

FIG. 24 applies the offset voltages (V_{DCL4}, V_{DCR4}) once and alternately to the metal electrodes 121 and 122, however, it is preferable to apply more than once at a predetermined time interval. Moreover, although the application time of the offset voltages defines one unit thereof as corresponding to two AC cycles, it can be determined arbitrarily, so as to be one cycle or one and a half cycle, for example.

According to the above, by applying the offset voltages alternately to the metal electrode 221 and the metal electrode 222, the silicon nanowires 233 arranged at angles and intersecting one another can be removed with higher efficiency. As a result, as schematically shown in FIG. 22, the silicon nanowires 231 arranged horizontally to the direction X are exclusively arranged, and the silicon nanowires are arranged within ±5 degrees with reference to the direction X.

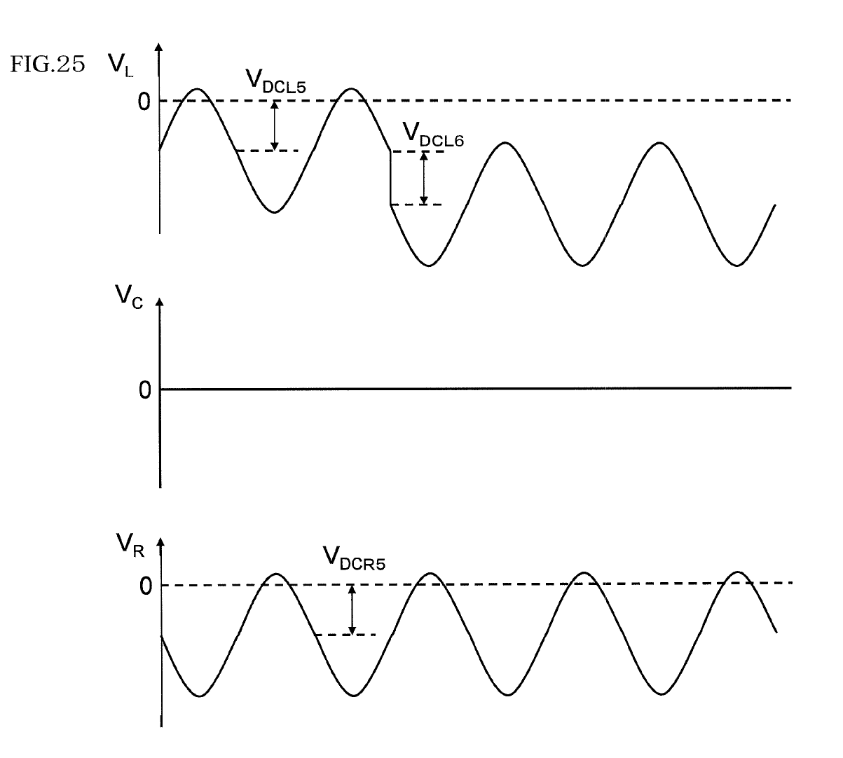

In a seventh method, as shown in FIG. 25, it is characterized by applying beforehand negative offset voltages (V_{DCL5}, V_{DCR5}) to the metal electrode 221 and the metal electrode 222.

By applying this example of the favorable voltages, there are obtained the effect achieved by the fifth method, as well as an effect described below.

Firstly, the negative offset voltages (V_{DCL5}, V_{DCR5}) are applied beforehand to both of the metal electrode 221 and the metal electrode 222. It has been clarified by observation that, due to this, the intervals W_{L} and W_{R} between the silicon nanowires shown in FIG. 14(a) are narrowed compared to a case where the negative offset voltages (V_{DCL5}, V_{DCR5}) were not applied. Specifically, when V_{PPL5}=V_{PPR5}=−0 V, that is, in the case of the fifth method, there was substantially established W_{L}=W_{R}=2.8 μm. On the other hand, in the seventh method, upon application satisfying V_{PPL5}=V_{PPR5}=−0.9 V, there was substantially established W_{L}=W_{R}=1.8 μm.

From these results, by varying the offset voltages to be applied to both of the electrodes, the intervals between the adjacent fine structures can be controlled. In the case of producing the semiconductor element by combining this controlling technique and the technique of arranging within ±5 degrees, the performance is improved, the yield is increased, and the variations can be suppressed.

Further, it has been clarified by observation that in the state of applying the negative offset voltages (V_{DCL5}, V_{DCR5}), when an offset voltage (V_{DCL6}) is further applied only to the metal electrode 221 (first electrode), the removal becomes easier compared to the fifth method.

The above mechanism is recognized as follows. In the state where the negative offset voltages (V_{DCL5}, V_{DCR5}) are applied beforehand, the intervals between the silicon nanowires are narrow, and thus, the arrangement is made at a high density. In such a state, by further applying the negative voltage (V_{DCL6}) to the metal electrode 221, a strong repulsive force is generated due to the intervals between the silicon nanowires being narrower than the case of the fifth method, and thereby it is regarded that the silicon nanowires 232 arranged at angles with respect to the direction X and the silicon nanowires 233 arranged at angles and intersecting one another are more easily removed.

Further, in the above case, the offset voltage (V_{DCL6}) to be further applied was negative, however, also in a case of being positive, the silicon nanowires 232 arranged at angles with respect to the direction X and the silicon nanowires 233 arranged at angles and intersecting one another can similarly be removed. The mechanism therefor is as described in the fifth method.

In FIG. 25, the negative offset voltages (V_{DCL5}, V_{DCR5}) are applied, however, positive offset voltages may be applied. Further, the negative offset voltage (V_{DCL6}) is applied once to the metal electrode 221 (first electrode), however, it is preferable to apply more than once at a predetermined interval. Moreover, the offset voltage (V_{DCL6}) shown in FIG. 25 was superimposed with the AC voltage and applied, however, the offset voltage (V_{DCL6}) may be applied after having applied the AC voltage.

According to the above, by applying the offset voltage to one of the electrodes in the state of applying the voltage for causing the arrangement as well as the offset voltage, the silicon nanowires 232 arranged at angles with respect to the direction X and the silicon nanowires 233 arranged at angles and intersecting one another are preferentially removed. As a result, as schematically shown in FIG. 22, the silicon nanowires 231 arranged horizontally to the direction X are exclusively arranged, and the silicon nanowires are arranged within ±5 degrees with reference to the direction X.

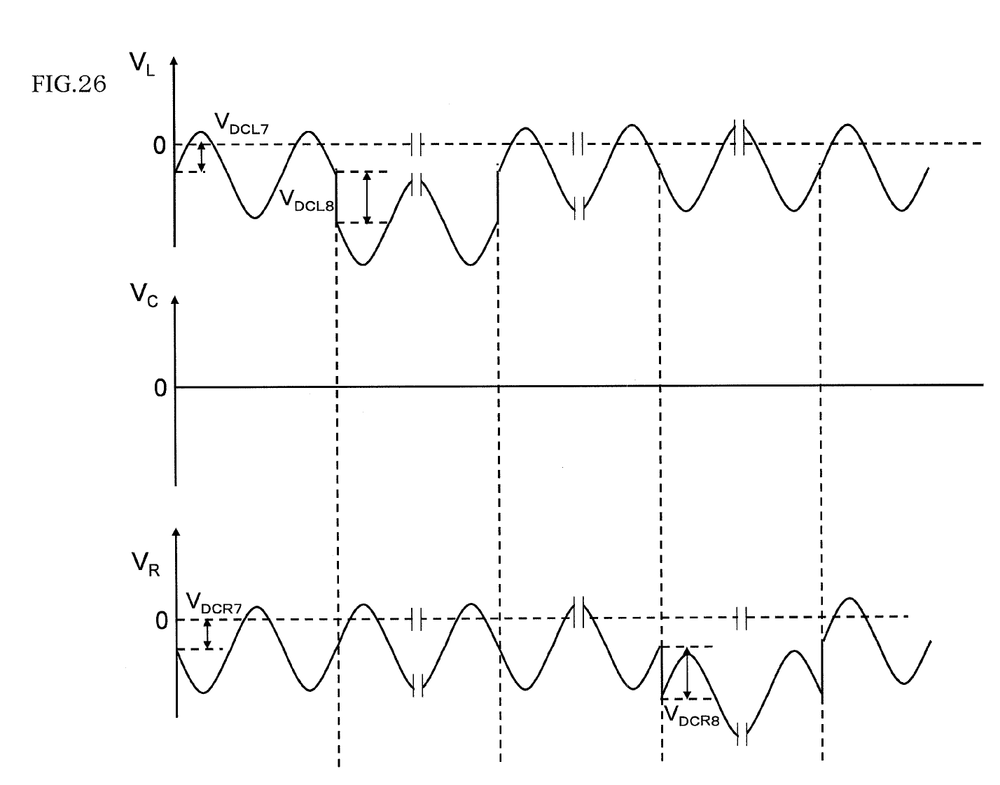

In an eighth method as shown in FIG. 26, alternately applied is the offset voltage (V_{DCL6}) exemplified in the seventh method to the metal electrodes 221 and 222. That is, identical negative offset voltages (V_{DCL7}, V_{DCR7}) are applied beforehand to the metal electrode 221 and the metal electrode 222, and further, offset voltages (V_{DCL8}, V_{DCR8}) are alternately applied to the metal electrode 221 and the metal electrode 222.

By using the eighth method, in addition to the effect achieved by the seventh method, the effect achieved by the sixth method can also be achieved.

Hence, by using this method, the silicon nanowires 232 arranged at angles with respect to the direction X and the silicon nanowires 233 arranged at angles and intersecting one another are preferentially removed. As a result, as schematically shown in FIG. 22, the silicon nanowires 231 arranged horizontally to the direction X are exclusively arranged, and the silicon nanowires are arranged within ±5 degrees with reference to the direction X.

### Embodiment 3

In the present embodiment 3, a semiconductor material is used for fine structures, arrangement is performed as explained in the above embodiment 1 or 2, to be applied to a semiconductor element. Herein, an integrated circuit in which the semiconductor elements are integrated will be explained as an example. As already described, in this embodiment 3, as shown in FIG. 1(b), the semiconductor element is configured by using the fine structures configured such that the silicon nanowire 41 is coated with the insulating layer 42 composed of a silicon dioxide film.

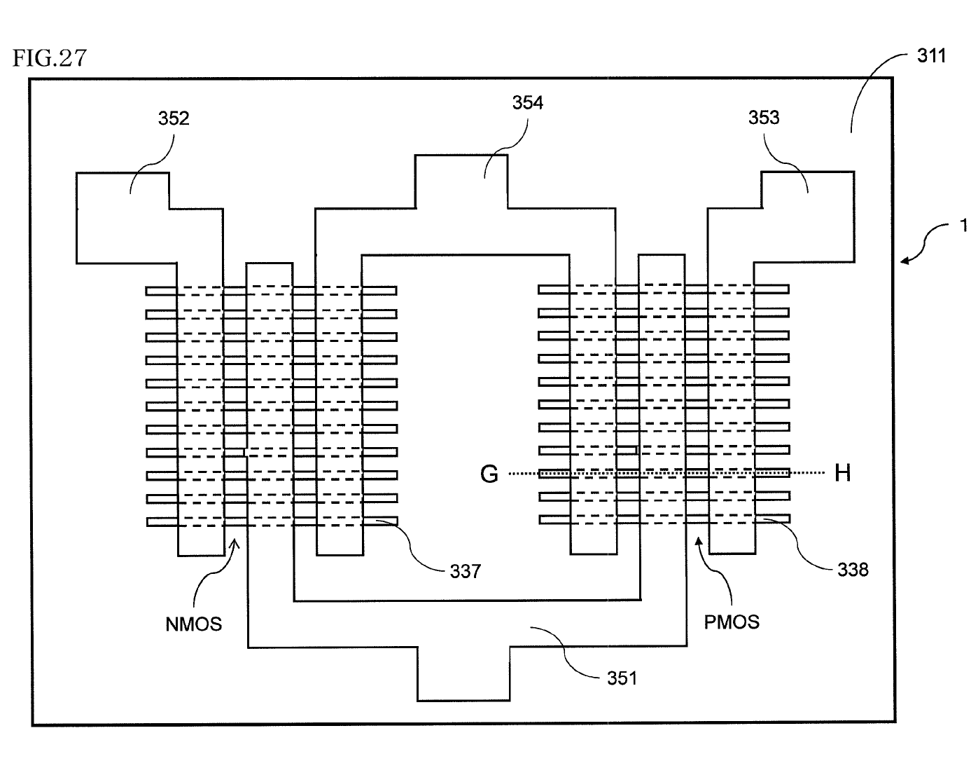

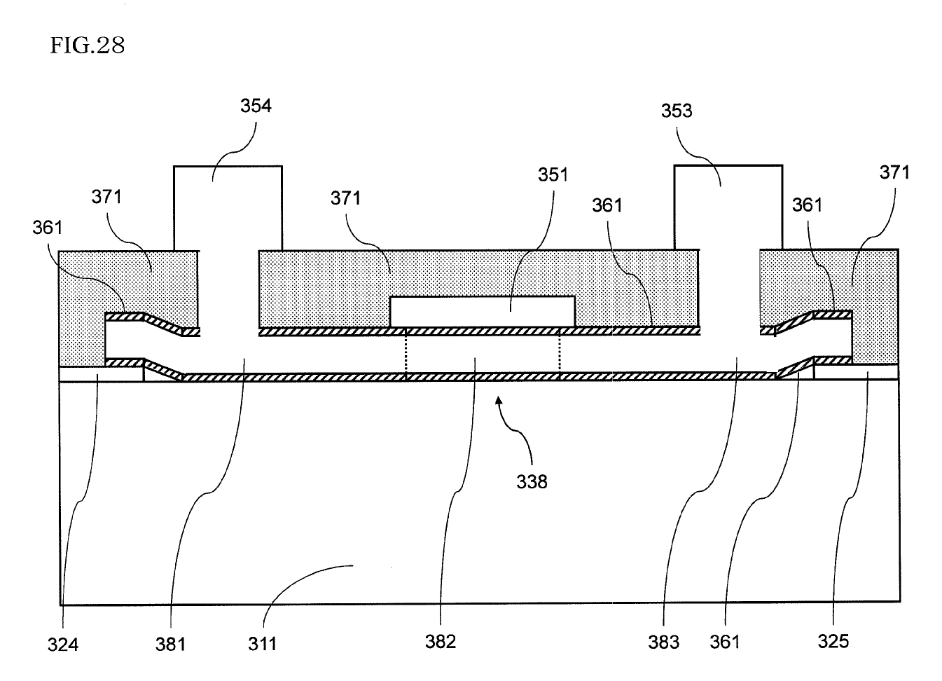

The present embodiment 3 will be explained with reference to FIG. 27 and FIG. 28. In the present embodiment 3, as a specific example of the integrated circuit device, a case in which two nanowire elements (of an N channel type and a P channel type) are disposed on one substrate will be described. Of course, the integrated circuit device of the present invention may include more than three elements that have different functions on the same substrate.

FIG. 27 is a plan view of an integrated circuit device 1 as a part of the integrated circuit device of the present invention. Note that, although not depicted in FIG. 27 for the sake of explanation, the integrated circuit device 1 of the present embodiment includes an interlayer insulating film 371 (shown in FIG. 28). A configuration of the interlayer insulating film 371 will be explained with reference to FIG. 28.

With reference to FIG. 27, on a substrate 311 that composes the integrated circuit device 1, two transistors having different functions are disposed; namely, an N-type field effect transistor (hereinbelow referred to as “NMOS: n type metal oxide semiconductor field effect transistor”) and a P-type field effect transistor (hereinbelow referred to as “PMOS: p type metal oxide semiconductor field effect transistor”). Further, elements to be disposed on the substrate 411 of the integrated circuit device 1 may be elements of different materials.

The NMOS is formed by arranging a plurality of nanowires 337, and the PMOS is formed by arranging a plurality of nanowires 338.

The nanowires 337 composing the NMOS and the nanowires 338 composing the PMOS have two shared wirings: namely, a metal wiring 351 and a metal wiring 354. Further, the nanowires 337 are connected to a metal wiring 352, and the nanowires 338 are connected to a metal wiring 353.

In the integrated circuit shown in FIG. 27, the metal wiring 351 is connected to an input terminal, and the metal wiring 354 is connected to an output terminal. Further, the metal wiring 352 is connected to a ground terminal, and the metal wiring 353 is connected to a power source terminal.

The above substrate 311 preferably has an insulating surface, and an insulator, a semiconductor with an insulating film formed on a surface thereof, a conductor with an insulating film formed on a surface thereof, or the like may favorably be used as the substrate of the present embodiment. Further, in a case of installing the integrated circuit device in a liquid crystal panel of a display device, it is preferable for the substrate 311 to be insulative and transparent. For example, a substrate of a material such as a glass or transparent resin may be exemplified.

The PMOS used in the present embodiment is composed by arranging the plurality of nanowires 338 as aforestated. Moreover, the single nanowire 338 has a function of the PMOS. The nanowires 338 used in the present embodiment will be explained using FIG. 28.

FIG. 28 shows a case in which the interlayer insulating film 371 is formed on the integrated circuit device 1 shown in FIG. 27, and is a cross sectional view along line G-H of FIG. 27. The nanowires 338 are arranged on the substrate 331, and each nanowire 338 is composed of a core made of a semiconductor such as a silicon material having a shape of a wire, and an insulating film 361 covering the core and being composed of silicon dioxide or the like. Moreover, the core includes a region 381 having a P-type conductivity, a region 382 having an N-type conductivity, and a region 383 having the P-type conductivity. Although the nanowire will be explained as a being made of silicon, it may be of a semiconductor material such as GaAs, GaN, SiC, or a carbon nanotube.

The metal wiring 351 is connected to the insulating film 361 at a center of the nanowire 338, and parts other than contacting portions with the nanowires 338, the substrate 311, the metal wiring 351, the metal wiring 352, and the metal wiring 354 are covered with the interlayer insulating film 371.

The above region 382 is connected to the metal wiring 351 via the insulating film 361, and functions as a channel region of the nanowire 338, by a function of the metal wiring 351 connected to the input terminal as a gate electrode. That is, the insulating film 361 covering the region 382 functions as a gate insulating film.

The core and the metal wiring 353 are connected by removing the insulating film 361 in the region 383. Further, the core and the metal wiring 354 are connected by removing the insulating film 361 in the region 381. The region 383 is connected to the metal wiring 353 connected to the power source terminal, and configures a source region of the nanowire 338. Further, the region 381 is connected to the metal wiring 354 connected to the output terminal, and configures a drain region of the nanowire 338.

In this case, the nanowires 232 arranged at angles or the nanowires 233 arranged intersecting one another are removed in accordance with the embodiment 1 or 2. Accordingly, the nanowires can be arranged within ±5 degrees with reference to the direction perpendicular to the electrode forming direction; and it is as already described that the case of forming the semiconductor using such silicon nanowires solves the technical problems stated earlier.

Note that, similarly to the above PMOS, the NMOS used in the present embodiment is composed by arranging the plurality of nanowires 337 as aforestated. Moreover, the single nanowire 337 has a function of the NMOS. The nanowires 337 used in the present embodiment are almost the same as the case with the nanowires 338 except that the conductivity is opposite from each other, thus the explanation thereof is not repeatedly provided.

Note that, in FIG. 28, reference signs 324 and 325 denote electrodes used upon arranging the nanowires. FIG. 27 does not depict the electrodes 324 and 325.

In the present embodiment, as already stated, the nanowire 337 functions as the NMOS, and the nanowire 338 functions as the PMOS. In order to configure the nanowire to be the NMOS or the PMOS, after having arranged the nanowires on the substrate in accordance with the embodiment 1 or the embodiment 2, impurity ions may be injected, and an activation annealing may be performed. Alternatively, nanowires to which the impurities may be introduced beforehand and which have gone through the activation annealing may be arranged on the substrate in accordance with the embodiment 1 or the embodiment 2. In the latter case, since the substrate is not exposed to a high temperature of the activation annealing, it is advantageous in that a flexible substrate can easily be fabricated.

In the former case, more specifically, in order to form the nanowire 337 as the NMOS, for example, at a stage where the metal wiring 351 is formed, this metal wiring 451 is used as a mask, and the impurity ions (such as arsenic ions) that endow the n-type conductivity is injected exclusively to a region where the nanowires 337 exist. Thereafter, in order to form the nanowire 338 as the PMOS, the metal wiring 351 is used as the mask, and the impurity ions (such as boronic ions) that endow the p-type conductivity is injected exclusively to a region where the nanowires 338 exist. Thereafter, the annealing (at 500° C. to 900° C., for example) can be performed for activation of impurities.

Note that, an injection concentration varies depending on a depth of the region. In this case, if the nanowires intersecting one another exist in the region to which the ions are to be injected, due to the depths of the intersecting nanowires being different, variations occur in the injection concentration. Hence, the aforesaid nanowires do not function as an element, or the performance thereof is significantly degraded. By using the embodiment 1 or embodiment 2 of the present invention, the aforesaid nanowires can be removed. As a result, the nanowires can be arranged within ±5 degrees, and the aforestated technical problems can be solved as already described.

In the latter case, nanowire having an impurity profile of n+/p/n+ (NMOS) or p+/n/p+ (PMOS) are formed in advance. In order to form such nanowires, for example, during the growing of the nanowire, impurities that endow the n-type conductivity, impurities that endow the p-type conductivity, and impurities that endow the n-type conductivity, may orderly be introduced (in a case of fabricating the nanowire having the n+/p/n+ configuration). After that, each nanowire may be arranged at the predetermined position on the substrate in accordance with the embodiment 1 and the embodiment 2.

Regarding an interlayer insulating film and an upper metal wiring, an LSI process or a process used in an LCD-TFT process can be applied.

The integrated circuit device 1 shown in FIG. 27 is an inverter circuit composed of the NMOS and the PMOS.

In the present embodiment, as a specific example of the combination of the NMOS and the PMOS, the inverter circuit (NOT circuit) is indicated. However, a circuit that can be configured by combining the nanowire elements of the present invention is not limited to this, and may configure an AND circuit, an NAND circuit, a NOR circuit, a XOR circuit, or the like. Further, even more complex logic circuit can be configured by combining these circuits.

As stated above, the integrated circuit device of the present embodiment has the nanowire elements of the present invention arranged in the direction perpendicular to the electrode forming direction, and the fine structures are arranged within ±5 degrees with reference to the perpendicular direction, thus, it becomes possible to greatly improve the performance, the yield, and the reliability of the integrated circuit device.

### Embodiment 4

The present embodiment is an example of an application of the fine structures arranged in accordance with the above embodiments to a display device.

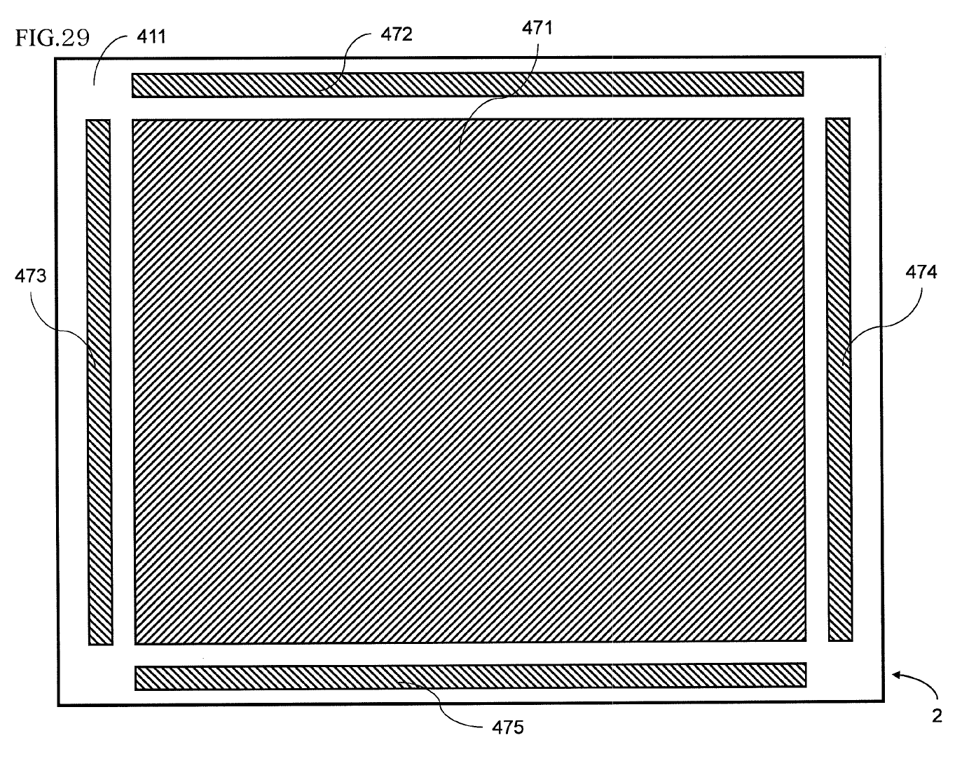

The display device that installs the integrated circuit device of the present invention will be described with reference to FIG. 29. FIG. 29 is a plan view of the display device of the present embodiment.

A display panel 2 of the display device is provided on a single transparent substrate 411 with a display unit 471 at a center portion, and a logic circuit unit 472, a logic circuit unit 473, a logic circuit unit 474 and a logic circuit unit 475 at four peripheral portions. In a case where the display device is a liquid crystal display device, in the display unit 471, nanowire transistors required for driving pixel electrodes and the pixel electrodes, etc. are formed in a matrix shape. Further, the logic circuits 472 to 475 are also formed by the nanowire transistors.

Further, in a case where light emitting elements composed of a plurality of nanowires are used instead of the pixel electrodes, a display device having the logic circuits and autonomous light emitting pixels within a display panel can be realized. As for the logic circuit unit 472, the logic circuit unit 473, the logic circuit unit 474, or the logic circuit unit 475, image processing and other operations are performed by the logic circuits composed of the nanowire transistors.

Conventionally, as a pixel driving transistor or image processing transistor, the TFT has been used, however, by substituting the TFT by the nanowire element, the following effect can be achieved.

Firstly, in forming a gate insulating film of a typical TFT, a CVD (Chemical Vapor Deposition) oxide film using TEOS (Tetraethylorthosillicate) is used. Due to this, the TFT has a low transconductance compared to a MOS transistor fabricated by using a single crystal silicon substrate that forms a gate insulating film by heat oxidation. Further, variations in the transconductance are larger.

On the other hand, the MOS transistor using the nanowires can use the single silicon crystal as the material for the core, and is capable of forming a surround-gate type fully-depleted transistor. Hence, the nanowire MOS transistor has a high transconductance compared to the conventional MOS transistor, and a transistor with small variations in the transconductance can be realized.

According to this, the display device of the present invention including the integrated circuit device and the display unit on the single substrate can have higher performance compared to the display device using the TFT. Consequently, a driving voltage of the display device can be lowered, and power consumption can be decreased.

Next, in order for the display device to be configured by having the TFT, the manufacture of the display device and the manufacture of the TFT cannot be performed independently, and thus, elaborate facility such as a vacuuming device, a deposition device, or the like in a large scale is required. However, because the manufacturing process of the silicon nanowires and the manufacturing process of the display device are independent from each other, the display device can be manufactured in a relatively small facility. As a result, a manufacturing cost of the display device can be significantly lowered.

Further, the display device of the present embodiment is capable of significantly improving the performance, variations, and the yield thereof by being formed in accordance with the present invention.

### INDUSTRIAL APPLICABILITY

According to the present invention, a semiconductor element having fine structures arranged with variations in the longitudinal direction within ±5 degrees can be fabricated. A switching element, a memory element, a light emitting element, a resistor element, or the like can be embodied as the semiconductor element, and may widely be applied to an integrated circuit device, a display device, or the like in which the semiconductor elements are integrated.

1. A semiconductor element comprising:
an insulating substrate on which at least two electrodes are arranged at a predetermined interval, and one or more fine structure arranging regions, each of which is formed by a unit of the two electrodes, are formed;
a plurality of fine structures, each having two ends in contact with the two electrodes, and a length of a nano order to a micron order, and arranged within ±5 degrees with reference to a direction perpendicular to a parallel direction along which the two electrodes are arranged; and
a semiconductor element electrode in contact with the plurality of the fine structures.

2. The semiconductor element according to claim 1, further comprising a third electrode arranged between the two electrodes.

3. The semiconductor element according to claim 1, wherein the predetermined interval is 1 μm to 30 μm.

4. The semiconductor element according to claim 1, wherein the plurality of the fine structures arranged between the two electrodes is arranged at substantially even intervals.

5. The semiconductor element according to claim 1, wherein the predetermined interval is 0.6 to 0.9 times the length of the fine structure.

6. The semiconductor element according to claim 1, wherein the fine structures are composed of a metal, a semiconductor, or a dielectric, and each have a shape of a wire, a tube, or a quantum wire.

7. The semiconductor element according to claim 1, wherein the fine structures are composed of lamination of a metal layer, a semiconductor layer, or a dielectric layer, and each have a shape of a wire, a tube or a quantum wire.

8. The semiconductor element according to claim 1, wherein the fine structure is a semiconductor material having an insulating film on a surface thereof, and the semiconductor element electrode includes an electrode in contact with the semiconductor material via the insulating film and an electrode in contact with the semiconductor material with the insulating film removed.

9. The semiconductor element according to claim 1, wherein the fine structure has a standard deviation of an angular distribution from 1 to 6 degrees, with reference to the direction perpendicular to the parallel direction along which the two electrodes are arranged.

10. A display element comprising:
the semiconductor element according to claim 1.

11. The display element according to claim 10, wherein the display element is a liquid crystal display element.

12. A method of manufacturing a fine structure arranging substrate, the method comprising:
a fine structure dispersed solution producing step of dispersing fine structures each having a length of a nano order to a micron order in a solution;
a substrate forming step of forming one or more fine structure arranging regions in each of which a first electrode and a second electrode are arranged on an insulating substrate at an interval shorter than the length of the fine structure;
an application step of applying the fine structure dispersed solution on the insulating substrate;
a fine structure arranging step of applying a voltage between the first electrode and the second electrode to arrange the fine structures in the fine structure arranging region; and
a removing step of removing the fine structure having undesirable arrangement after the fine structure arranging step.

13. The method of manufacturing the fine structure arranging substrate according to claim 12, wherein the removing step includes an offset voltage applying step of applying an offset voltage to the first electrode or the second electrode.

14. The method of manufacturing the fine structure arranging substrate according to claim 12, wherein the removing step includes an offset voltage alternate application step of alternately applying an offset voltage to the first electrode and the second electrode.

15. The method of manufacturing the fine structure arranging substrate according to claim 12, wherein in the fine structure arranging step, an AC voltage is applied, and in the removing step, the AC voltage and the offset voltage are superimposingly applied to the first electrode or the second electrode.

16. The method of manufacturing the fine structure arranging substrate according to claim 12, wherein in the fine structure arranging step, an AC voltage is applied, and in the removing step, the AC voltage and the offset voltage are superimposingly applied alternately to the first electrode and the second electrode.

17. A method of manufacturing a fine structure arranging substrate, the method comprising:
a fine structure dispersed solution producing step of dispersing fine structures each having a length of a nano order to a micron order in a solution;
a substrate forming step of forming one or more fine structure arranging regions in each of which a first electrode and a second electrode are arranged on an insulating substrate at an interval shorter than the length of the fine structure, and the second electrode is arranged in between the first electrode and a third electrode;
an application step of applying the fine structure dispersed solution on the insulating substrate;
a fine structure arranging step of applying a voltage between the first electrode and the third electrode to arrange the fine structures in the fine structure arranging region; and
a removing voltage applying step of applying a voltage for removing the fine structure having undesirable arrangement to the first electrode or the third electrode after the fine structure arranging step.

18. The method of manufacturing the fine structure arranging substrate according to claim 17, wherein the removing voltage applying step includes an offset voltage applying step of applying an offset voltage to the first electrode or the third electrode.

19. The method of manufacturing the fine structure arranging substrate according to claim 18, wherein the offset voltage applying step includes an offset voltage alternate application step of alternately applying the offset voltage to the first electrode and the third electrode.

20. The method of manufacturing the fine structure arranging substrate according to claim 17, wherein the fine structure arranging step includes a three-terminal AC voltage applying step of applying a reference voltage to the second electrode and applying to the first electrode and the third electrode AC voltages of which voltage average is equal to the reference voltage applied to the second electrode, and an offset voltage applying step of applying an offset voltage to the first electrode or the third electrode during the three-terminal AC voltage applying step.

21. The method of manufacturing the fine structure arranging substrate according to claim 20, wherein the three-terminal AC voltage applying step includes an offset voltage alternate application step of alternately applying the offset voltage to the first electrode and the third electrode.

22. The method of manufacturing the fine structure arranging substrate according to claim 21, wherein the fine structure arranging step includes a three-terminal offset voltage superimposed AC voltage applying step of applying the reference voltage to the second electrode and applying an offset voltage superimposed AC voltage in which the offset voltage is superimposed to the reference voltage to the first electrode and the third electrode, and an offset voltage applying step of applying the offset voltage to the first electrode or the third electrode during the three-terminal offset voltage superimposed AC voltage applying step.

23. The method of manufacturing the fine structure arranging substrate according to claim 22, wherein the three-terminal offset voltage superimposed AC voltage applying step includes an offset voltage alternate application step of alternately applying the offset voltage to the first electrode and the third electrode.
